(19) United States
(12) Patent Application Publication
(10) Pub. No.: US 2025/0254841 A1
(43) Pub. Date: Aug. 7, 2025

(54) SYSTEMS AND METHODS FOR COOLING INFORMATION TECHNOLOGY EQUIPMENT

(71) Applicant: INERTECH IP LLC, Plano, TX (US)

(72) Inventors: Michael Welch, Mckinney, TX (US); Rick Sparkman, Phoenix, AZ (US); Mark Torres, Denton, TX (US); Travis Ciccarello, Chandler, AZ (US)

(73) Assignee: Inertech IP LLC, Plano, TX (US)

(21) Appl. No.: 19/043,103

(22) Filed: Jan. 31, 2025

Related U.S. Application Data
(63) Continuation of application No. PCT/US2024/057187, filed on Nov. 22, 2024.
(60) Provisional application No. 63/613,044, filed on Dec. 20, 2023.
(60) Provisional application No. 63/602,349, filed on Nov. 22, 2023.

(51) Int. Cl. H05K 7/20

(52) U.S. Cl. CPC H05K 7/2079; H05K 7/20272; H05K 7/20745

(57) ABSTRACT

Data center assemblies include first and second arrays of information technology (IT) equipment cabinets defining a hot aisle. The data center assemblies also include an air containment assembly fluidly coupled to the hot aisle, at least one air-cooling unit fluidically coupled the air containment assembly, and/or at least one liquid-cooling system fluidically coupled to at least a portion of the IT equipment cabinets. The at least one fluid-cooling system includes a heat exchanger fluidically coupled to a cooling liquid loop and a fluid pump fluidly coupled to the heat exchanger and the at least a portion of the IT equipment cabinets. The air-cooling units and liquid-cooling systems may be designed to be interchangeable, allowing for seamless adaptation to changes in the number and types of IT equipment cabinets in a data center pod. The types of IT equipment cabinets may include air-cooled and liquid-cooled IT equipment cabinets.

### FIELD

The technology of the disclosure is generally related to cooling of information technology (IT) equipment deployed within data centers. The technology incorporates a liquid-to-liquid coolant distribution unit (CDU) supporting liquid-cooled servers disposed within a data center.

### BACKGROUND

There are an increasing number of applications requiring greater processing power. For example, machine learning and artificial intelligence applications require the training of large neural network models including large convolutional neural network models. Computer graphics applications generate complex graphics. Scientific computing applications involve simulations, including physics and fluid dynamics simulations, and other scientific computations. And data analysis applications involve processing and analyzing vast amounts of data.

Specialized processing units are being developed and used to meet the ever growing demands for computational power. For example, the GPU (Graphics Processing Unit) provides parallel processing capabilities, which can significantly reduce computation time. The GPUs may be interconnected and used collectively in a GPU cluster. As the load increases, GPU nodes may be added to the GPU cluster to handle the increased load. As another example, a TPU (Tensor Processing Unit) is an application-specific integrated circuit (ASIC) developed for accelerating machine learning workloads, by optimizing tensor computations. Like GPUs, TPUs may be interconnected and used collectively in a TPU cluster.

The GPU and TPU clusters needed to run artificial intelligence (AI), machine learning (ML), deep learning, high-performance computing (HPC), and large-scale cloud computing applications require massive processing power, pushing densities far beyond the average kilowatt (KW) per server rack. Therefore, there is a need for cooling technology to address the increased densities.

### SUMMARY

The technology of this disclosure generally relates to providing cooling fluid to server deployments within a data center, which require liquid cooling in lieu of or in addition to air cooling. The technology of this disclosure may seamlessly integrate with chilled water systems or other IT equipment cooling systems. The technology of this disclosure may also seamlessly enable a transition from air cooling to liquid cooling, or a combination or splitting of cooling technologies in the same row of a data hall in a data center, which minimizes any impacts on existing cooling infrastructure by an installation process. By enabling seamless transitions between cooling types, the cooling systems of the disclosure can adapt dynamically to evolving computational and thermal demands while minimizing operational disruption and costs.

In one aspect, the disclosure features a cooling system. The cooling system includes a heat exchanger configured to be fluidically coupled to a facility fluid cooling circuit, a fluid pump fluidically coupled to the heat exchanger configured to pump cooling fluid to at least a portion of IT cabinets of two rows of IT cabinets defining a hot aisle, an electrical panel electrically coupled to the fluid pump, and a control panel electrically coupled to the electrical panel and operationally coupled to the fluid pump. The cooling system also includes an array of fan and heat exchanger modules fluidically coupled to the facility cooling fluid circuit and disposed adjacent to the CDU. The array of fan and heat exchanger modules are configured to circulate (e.g., push) air through the hot aisle.

In aspects, implementations of the cooling system may include one or more of the following features. The CDU may include an uninterruptible power supply electrically coupled to the fluid pump. The electrical panel may include a switch or other suitable power transfer component electrically coupled to power supply feeds or incoming power connections. A power supply feed of the power supply feeds may be electrically coupled to an electrical generator. Another power supply feed of the power supply feeds may be electrically coupled to a mains power supply. A fluid line may be coupled between the fluid pump and the heat exchanger. The cooling system may include supply and return line coupling members coupled to a side of the CDU. The supply and return line coupling members may include quick-connect fittings. The fluid pump may be a liquid pump. The liquid pump may be a water pump.

In another aspect, this disclosure features a data center assembly. The data center assembly includes a first array of IT equipment cabinets, and a second array of IT equipment cabinets disposed adjacent to the first array of IT equipment cabinets to define a hot aisle. The data center assembly also includes an air containment assembly fluidically coupled to the hot aisle, at least one array of fan and heat exchanger modules fluidically coupled to the air containment assembly, and at least one fluid-cooling system fluidically coupled to at least a portion of the IT equipment cabinets. The at least one fluid-cooling system includes a heat exchanger fluidically coupled to a portion of the first and second arrays of IT equipment cabinets, and fluidically coupled to a facility fluid cooling loop, a fluid pump fluidically coupled to the heat exchanger, an electrical panel electrically coupled to the fluid pump, and a control panel electrically coupled to the electrical panel and operationally coupled to the fluid pump.

In aspects, implementations of the data center assembly may include one or more of the following features. The fluid pump may be a liquid pump. The liquid pump may include a water pump. A technology cooling fluid circuit may be positioned below a subfloor of a data center. The first and second arrays of IT equipment cabinets are fluidically coupled to the technology cooling fluid circuit through flexible lines. The electrical panel may include a switch electrically coupled to power supply feeds. A power supply feed of the power supply feeds may be electrically coupled to an electrical generator. Another power supply feed of the power supply feeds may be electrically coupled to a mains power supply. A technology cooling fluid circuit may be positioned adjacent to the first and second arrays of IT equipment cabinets. The technology cooling fluid circuit may fluidically couple to a top portion or a side portion of the first and second arrays of IT equipment cabinets.

The at least one array of fan and heat exchanger modules may include at least two arrays of fan and heat exchanger modules. The at least one fluid-cooling system may be disposed between the at least two arrays of fan and heat exchanger modules. The at least one fluid-cooling system may include at least two fluid-cooling systems. The at least one fluid-cooling system may include three fluid-cooling systems. The at least one array of fan and heat exchanger modules may include at least two fan and heat exchanger modules stacked in a vertical direction.

In another aspect, this disclosure features a method of designing a data center cooling system. The method includes receiving server rack information and determining types of server racks based on the server rack information. The method also includes determining cooling parameters for each of the server racks and determining at least one cooling modality based on the determined types of server racks and the determined cooling parameters for each of the server racks. The method also includes determining a number of cooling systems of the at least one cooling modality based on the cooling parameters for each of the server racks and displaying information regarding the determined number of cooling systems of the at least one cooling modality.

In aspects, implementations of the method of designing a data center cooling system may include one or more of the following features. The at least one cooling modality may include an air-cooling modality or a liquid-cooling modality. The method may include determining a number of air-cooling units for the air-cooling modality. The method may include determining a number of fan and heat exchanger modules in the air-cooling units. The liquid-cooling modality may include a water-cooling modality or a refrigerant-cooling modality.

In aspects, displaying information may include displaying a graphical representation of the arrangement of cooling systems in the data center pod. The method may include determining a number of coolant distribution units for the liquid-cooling modality. The method may include in response to determining an air-cooling modality and a liquid-cooling modality, determining an arrangement of air-cooled server racks and liquid-cooled server racks. Determining the arrangement of air-cooled server racks and liquid-cooled server racks may include determining to arrange air-cooled server racks between liquid-cooled server racks.

In aspects, the method may include determining a number of data center pods based on the cooling parameters for each of the server racks. The method may include determining one or more types of data center pods for the data center. The types of data center pods may include air-cooled data center pods, liquid-cooled data center pods, or hybrid air- and liquid-cooled data center pods.

In another aspect, this disclosure features a method of managing a data center cooling system. The method includes receiving updated information for a data center pod, detecting a change in the data center pod based on the updated information, and determining the type of server racks associated with the detected change in the data center pod. The method also includes determining new total cooling parameters for all server racks of the determined type in the data center pod. The method also includes comparing the new total cooling parameters with current cooling parameters of the cooling system configured for the determined type of server racks, and determining a change to the cooling system configured for the determined type of server racks based on the comparison.

In aspects, implementations of the method of managing a data center cooling system may include one or more of the following features. Determining the change to the cooling system may include determining to replace at least a portion of an existing cooling modality with a different cooling modality. Determining the change to the cooling system may include determining to replace an air-cooling unit with a coolant distribution unit (CDU). In aspects, the width of the air-cooling unit is the same as or substantially the same as the width of the CDU.

In aspects, determining the change to the cooling system includes determining to replace a CDU with an air-cooling unit. In aspects, determining the change to the cooling system may include determining to add a different cooling modality to the cooling system. The different cooling modality may be a gas-cooling modality or a liquid-cooling modality. The liquid-cooling modality may include a water-cooling modality or a refrigerant-cooling modality. The gas-cooling modality may include an air-cooling modality.

In aspects, the type of server racks and air-cooled server racks or liquid-cooled server racks. Determining the change to the cooling system may include determining a number of CDUs and/or air-cooling units to add to the cooling system. The method may include displaying a user interface indicating the change to the cooling system. The user interface may display a graphical representation of a new arrangement of at least one of CDUs, air-cooling units, or server racks.

In aspects, determining a change to the cooling system may include: determining to change the cooling system to include a gas-cooling modality and a liquid-cooling modality, and determining arrangement of new gas-cooled server racks and new liquid-cooled server racks. Determining the arrangement of the new gas-cooled server racks and the new liquid-cooled server racks may include determining to arrange the new gas-cooled server racks between the new liquid-cooled server racks.

In another aspect, this disclosure features a data center pod. The data center pod includes a first array of IT equipment cabinets, and a second array of IT equipment cabinets disposed adjacent to the first array of IT equipment cabinets to define a hot aisle. The data center pod also includes an air containment assembly fluidically coupled to the hot aisle and at least one air-cooling unit fluidically coupled to the air containment assembly. The data center pod also includes a technology liquid loop and at least one liquid distribution unit fluidically coupled through the technology liquid loop to a portion of the IT equipment cabinets.

The at least one liquid distribution unit includes a heat exchanger fluidically coupled to a cooling liquid loop and to the technology liquid loop. The heat exchanger facilitates heat transfer from the technology liquid loop to the cooling liquid loop. The at least one liquid distribution unit also includes a fluid pump fluidically coupled to the technology liquid loop.

In aspects, implementations of the data center pod may include one or more of the following features. The IT equipment cabinets may be server racks. The at least one air-cooling unit may include at least two fan and heat exchanger assemblies.

In aspects, at least one dimension of the at least one air-cooling unit may be the same as or substantially the same as at least one dimension of the at least one liquid distribution unit. The at least one dimension may be width. The at least one dimension may be width and height.

In aspects, the at least one liquid distribution unit may include an electrical panel electrically coupled to the fluid pump and configured to supply power to the fluid pump. The at least one liquid distribution unit may include a control panel in communication with the fluid pump and configured to control to the fluid pump. The at least one liquid distribution unit may include a strainer fluidically coupled to the fluid pump. The at least one liquid distribution unit may include isolation valves fluidically coupled to the technology liquid loop.

In aspects, the at least one air-cooling unit may be designed to be or substantially to be interchangeable with the at least one liquid distribution unit. The IT equipment cabinets may include air-cooled IT equipment cabinets and liquid-cooled IT equipment cabinets. The air-cooled IT equipment cabinets may be disposed between liquid-cooled IT equipment cabinets.

In aspects, the data center pod may include a third array of IT equipment cabinets, and a fourth array of IT equipment cabinets disposed adjacent to the third array of IT equipment cabinets to define a second hot aisle. The data center may include a second air containment assembly fluidically coupled to the second hot aisle and technology liquid branch lines fluidically coupled to a portion of the IT equipment cabinets and to the technology liquid loop. The technology liquid branch lines are disposed above or below the first and second hot aisles. In aspects, the liquid-cooled IT equipment cabinets include fluid line connectors coupled to a top portion or a side portion of the liquid-cooled IT equipment cabinets.

In aspects, the data center pod includes connection lines fluidically coupled between the technology liquid branch lines and the fluid line connectors. The connection lines include flexible piping or flexible hoses.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF DRAWINGS

FIG. 1 is a perspective view of a data center pod assembly that illustrates an air-cooling system assembly.

FIG. 2 is a perspective view of another data center pod assembly that illustrates an air- and liquid-cooling system assembly.

FIG. 3 is a perspective view of still another data center pod assembly that illustrates another air- and liquid-cooling system assembly.

FIG. 4 is a perspective view of still another data center pod assembly that illustrates still another air- and liquid-cooling system assembly.

FIG. 5 is a perspective view of the data center pod assembly of FIG. 1 that illustrates cooling arrays.

FIG. 6 is a perspective view of the data center pod assembly of FIG. 2 that illustrates a liquid-cooling distribution assembly.

FIG. 7 is a perspective view of the data center pod assembly of FIG. 3 that illustrates another liquid-cooling distribution assembly.

FIG. 8 is a perspective view of the data center pod assembly of FIG. 4 that illustrates still another liquid-cooling distribution assembly.

FIG. 9 is a perspective view of a coolant distribution unit (CDU) according to aspects of the disclosure.

FIG. 10A is a top view of the coolant distribution unit of FIG. 9.

FIG. 10B is a front view of the coolant distribution unit of FIG. 9.

FIG. 10C is a side view of the coolant distribution unit of FIG. 9.

FIG. 11 is a transparent perspective view of the coolant distribution unit of FIG. 9.

FIG. 12A is a fluid circuit block diagram that illustrates a technology fluid side of an information technology cooling system.

FIG. 12B is a fluid circuit block diagram that illustrates a facility fluid side of the information technology cooling system.

FIG. 13 is a perspective view of data center pod assemblies coupled to air and/or liquid cooling system assemblies.

FIG. 14 is a perspective view of an air- and liquid-cooling system assembly.

FIG. 15 is a perspective view of an air- and liquid-cooling system assembly coupled to supply and return lines.

FIG. 16 is a perspective view of data center pod assemblies coupled to air and/or liquid cooling system assemblies.

FIG. 17 is a diagram that illustrates examples of various liquid cooling requirements.

FIG. 18 is a perspective view of an air- and liquid-cooling system assembly coupled to supply and return lines disposed in a subfloor of a datacenter facility.

FIGS. 19A-19E are perspective views of the supply and return lines of FIG. 18 disposed in and along a subfloor of a hot aisle and coupled to supply and return branch lines to and from IT equipment cabinets.

FIGS. 20A-20C are perspective views that illustrate the expansion from a first air- and liquid-cooling system assembly to a second air- and liquid-cooling system assembly with greater cooling capacity than the first air- and liquid-cooling system assembly.

FIG. 21 is a perspective, exploded view of a data center pod illustrating an air- and liquid-cooling system, air-cooled server racks, and liquid-cooled server racks.

FIG. 22 is a perspective view of a CDU and a fan and heat exchanger assembly illustrating interchangeability between the CDU and the fan and heat exchanger assembly.

FIG. 23 is a perspective view of a CDU coupled to facility and technology liquid loops.

FIGS. 24 and 25 are perspective views of liquid-cooled server racks illustrating side and top connections to the liquid branch lines.

FIG. 26 is a flow chart illustrating a method of designing a data center cooling system.

FIG. 27 is a flow chart illustrating a method of managing a data center cooling system.

FIG. 28 is a perspective view of another example of a CDU in accordance with aspects of the disclosure.

FIG. 29 is a schematic diagram of a fluid circuit for the CDU of FIG. 28;

FIGS. 30-36 are schematic diagrams of an electrical system for the CDU of FIG. 28.

FIG. 37 is a front view of fan and heat exchanger arrays in accordance with aspects of the disclosure;

FIG. 38 is an exploded view of a fan and heat exchanger array assembly including two fan and heat exchanger arrays.

FIGS. 39A and 39B are cutaway perspective views of a fan and heat exchanger assembly.

FIG. 39C is a perspective view of the fan and heat exchanger assembly of FIGS. 39A and 39B.

FIG. 39D is an exploded view of the fan and heat exchanger assembly of FIGS. 39A and 39B.

### DETAILED DESCRIPTION

The GPU and TPU clusters essential to running artificial intelligence (AI), machine learning (ML), deep learning, high-performance computing (HPC) and next-generation systems and applications require massive processing power, pushing densities beyond the average power per server rack. The scalable infrastructure and flexible cooling technologies of this disclosure meet the increased density needs and rising temperatures of these technologies.

The technology of the disclosure enables the use of air cooling, liquid cooling, or hybrid air and liquid cooling. Existing CDU products cannot be deployed “like for like” with an associated product that can cool IT equipment using air. The technology of the disclosure may seamlessly integrate with chilled water infrastructure enabling deployment of both air- and liquid-cooling products in parallel. The cooling technology of the disclosure addresses the needs of future data centers requiring the installation of both air- and liquid-cooling systems.

The technology of the disclosure is a scalable and universal architecture, which supports all current and future cooling requirements, and brings cooling fluid closer to the server cabinets. The technology brings the right balance of turnkey solutions and customization to provide customers with flexible data center designs within a standardized delivery process to streamline the deployment and reduce cost impacts, time delays, and risk. The technology is sustainable and efficient. The technology is designed with efficiency in mind, leveraging standard closed loop systems, using no outside air or water. The technology seamlessly shifts to liquid cooling or integrates liquid-cooled systems in the same row of a data hall as existing air-cooled infrastructure in a live environment. The technology requires no complete retrofit or separate build-to-suit.

The technology includes a modular approach to liquid cooling. The technology supports vertical increases in density within the server cabinet and horizontal increases in density with the addition of server cabinets. The technology provides seamless integration with existing air-cooling technology including fan and heat exchanger assemblies, leaves power requirements unchanged, and is compatible with existing facility water temperatures. The technology may support the hardware and processing requirements of the AI, ML and HPC lifecycle, from training to real-time inference.

The technology offers customers the flexibility to seamlessly pivot and scale to support shifting computing environments no matter the customer's applications, density requirements, or cooling solutions. The technology makes it simple for customers to transition from air-cooled to liquid-cooled systems or deploy hybrid cooling systems combining both air and liquid in the same data center, eliminating the need to construct new AI-dedicated build-to-suit data centers or completely retrofit and/or retool existing facilities. The technology may be capable of handling a wide range of server heat loads, cooling densities of, for example, 3 kW to 300 kW per server rack, while still maintaining designs based on standard, closed-loop systems.

Thus, the technology of the disclosure may be a turnkey solution delivered within a standardized delivery process to streamline liquid-cooled deployments. The scalable, universal architecture of this disclosure supports customers' customization requirements as well as integration with various liquid cooling technologies, including direct-to-chip, rear-door heat exchangers, and immersion cooling. The technology may also integrate seamlessly with existing air-cooled technology, requiring no changes in power delivery or existing data center temperatures, and making the transition from air cooling to liquid cooling or hybrid air and liquid cooling seamless, even in live environments.

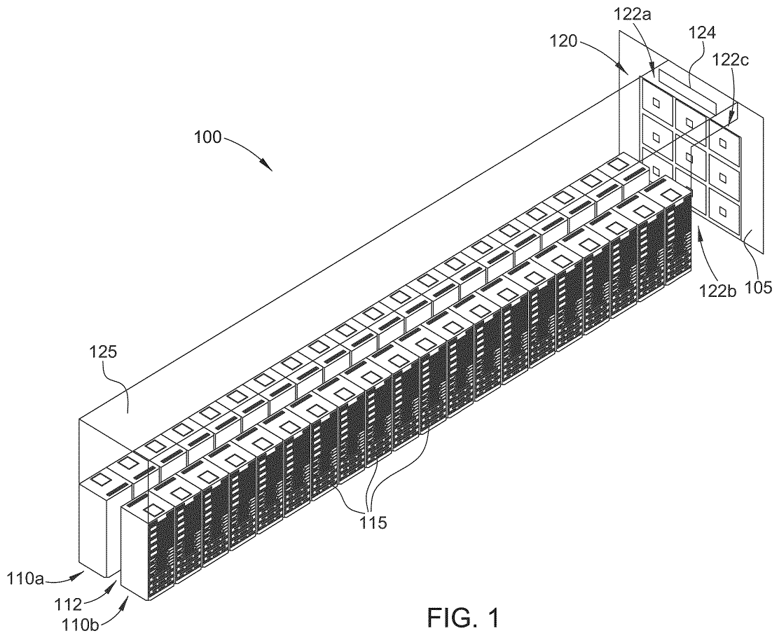

FIG. 1 illustrates an air-cooled data center pod 100, which includes an air-cooling system assembly 120. The air-cooling system assembly 120 includes three air-cooling units 122a-122c. Although, in other aspects, the air-cooling system assembly 120 may include less than or greater than three air-cooling units. As illustrated, the air-cooling units 122a-122c each include three stacked fan and heat exchanger assemblies. In other aspects, one or more of the air-cooling units 122a-122c may include less than or greater than three stacked fan and heat exchanger assemblies. The air-cooled data center pod 100 also includes two arrays 110a, 110b of server cabinets 115 facing away from each other and forming a hot aisle 112. While the illustrated server cabinet arrays 110a, 110b each includes twenty server cabinets 115, this disclosure contemplates server cabinet arrays including any number of server cabinets, e.g., ten, fifteen, or fifty server cabinets. The number of server cabinets 115 in a server cabinet array may be limited or dictated by the cooling capacity of the air-cooling system assembly and the cooling requirements of the server cabinets 115.

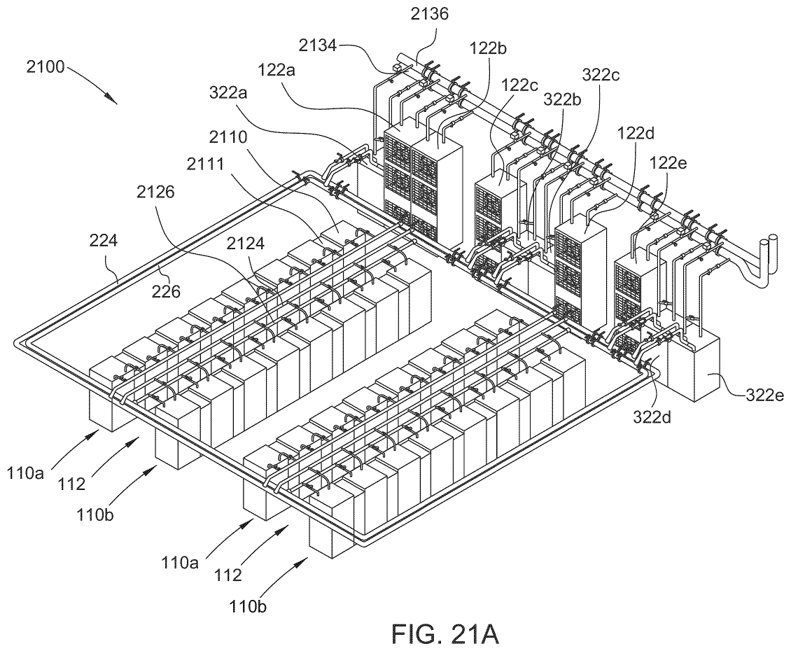

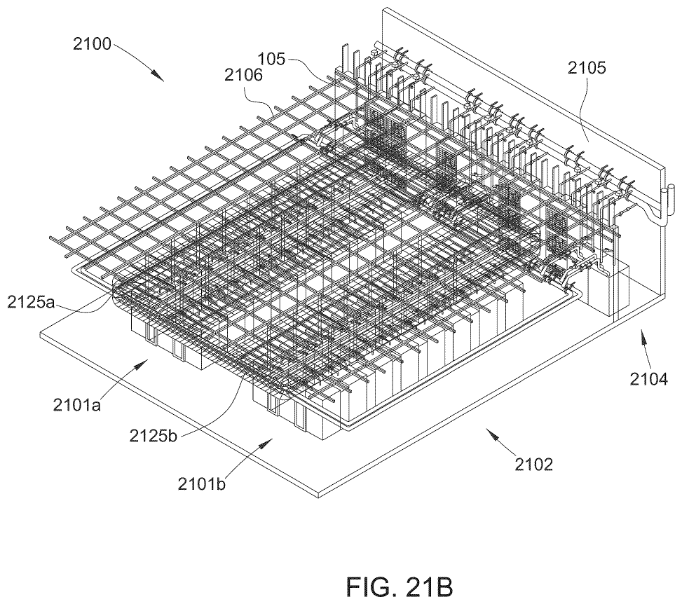

A containment assembly 125 is fluidically coupled to and disposed above the hot aisle 112. The containment assembly 125 is also fluidically coupled to an aperture 124 in an interior wall 105 of the data center building. The interior wall 105 may be coupled to a drop ceiling, e.g., the drop ceiling 2106 shown in FIG. 21B. The interior wall 105 may form a portion of an enclosure that collects heated air from the containment assembly 125 before the heated air is drawn through and cooled by the air-cooling units 122a-122c. In one aspect, the interior wall 105 and the exterior wall of the data center building, e.g., the exterior wall 2105 shown in FIG. 21B, may form a portion of the enclosure that collects heated air flowing from the containment assembly 125.

In one example, each of the fan and heat exchanger assemblies may have a cooling capacity of 275 kW. Thus, an air-cooling unit having three fan and heat exchanger assemblies may have a cooling capacity of 3×275 kW=825 kW. And three air-cooling units may have a total cooling capacity of 3×825 kW=2.475 MW. Therefore, for the data center pod 100 illustrated in FIG. 1, the three air-cooling units 122a-122c may have the capacity, for example, to cool forty server cabinets averaging 60 kW each.

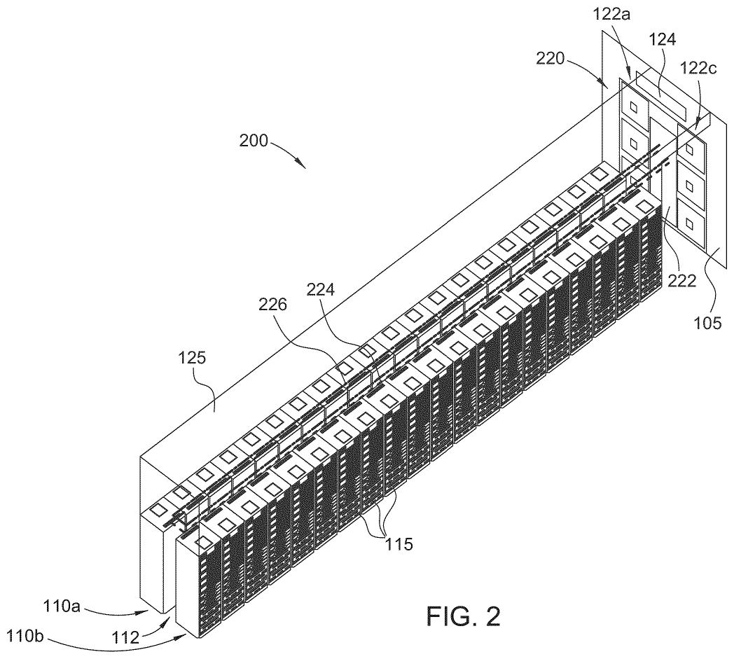

FIG. 2 illustrates a mixed air- and liquid-cooled data center pod 200, which includes an air- and liquid-cooling system assembly 220. In this example, the air- and liquid-cooling system assembly 220 includes two air-cooling units 122a, 122c, and one liquid cooling system 222, which may be implemented as a coolant distribution unit (CDU). The data center pod 200 also includes two arrays of server cabinets 110a, 110b facing away from each other and forming a hot aisle 112. While the illustrated server cabinet arrays 110a, 110b each includes twenty server cabinets, this disclosure contemplates server cabinet arrays including any number of server cabinets. The number of server cabinets in a server cabinet array may be limited or dictated by the cooling capacity of the air- and liquid-cooling system assembly and the cooling requirements of the server cabinets.

A containment assembly 125 is fluidically coupled to and disposed above the hot aisle 112. The containment assembly 125 is also fluidically coupled to an aperture 124 in the interior wall 105 of the data center building. The interior wall 105 may form a portion of an enclosure that collects heated air from the containment assembly 125 before the heated air is cooled by the air-cooling units 122a, 122c. In one aspect, the interior wall 105 and the exterior wall, e.g., the exterior wall 2105 shown in FIG. 21B, of the data center building may form a portion of the enclosure that collects heated air flowing from the containment assembly 125.

In one example, each of the fan and heat exchanger assemblies may have a cooling capacity of 275 kW. Thus, two air-cooling units 122a, 122c having three fan and heat exchanger assemblies may have a cooling capacity of 6×275 kW=1.65 MW. And the liquid cooling system 222 may have a cooling capacity of 500 kW. Thus, the liquid cooling system 222 and the two air-cooling units may have a total cooling capacity of 500 kW+1.65 MW=2.15 MW. Therefore, for the data center pod 200 illustrated in FIG. 2, the liquid cooling system 222 and the two air-cooling units 122a, 122c may have the capacity, for example, to cool forty server cabinets averaging 50 kW each.

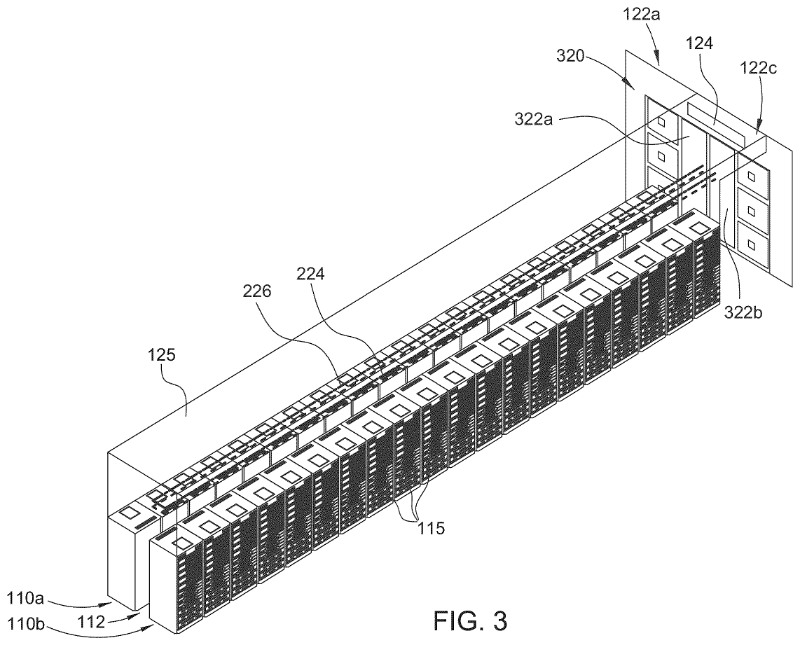

FIG. 3 illustrates another mixed air- and liquid-cooled data center pod 300, which includes another air- and liquid-cooling system assembly 320. The air- and liquid-cooling system assembly 320 includes two air-cooling units 222a, 222b, and two liquid-cooling system assemblies 222a, 222b. The data center pod 300 also includes two arrays of server cabinets 110a, 110b facing away from each other and forming a hot aisle 112. While the illustrated server cabinet arrays 110a, 110b each includes twenty server cabinets 115, this disclosure contemplates server cabinet arrays including any number of server cabinets. The number of server cabinets in a server cabinet array may be limited or dictated by the cooling capacity of the air- and liquid-cooling system assembly 300 and the cooling requirements of the server cabinets 115.

A containment assembly 125 is fluidically coupled to and disposed above the hot aisle 112. The containment assembly 125 is also fluidically coupled to an aperture 124 in an interior wall 105 of the data center building. The interior wall 105 may form a portion of an enclosure that collects heated air from the containment assembly 125 before the heated air is cooled by the two arrays of fan and heat exchanger assemblies and the two liquid cooling systems. In one aspect, the interior wall 105 and the exterior wall of the data center building may form a portion of the enclosure that collects heated air flowing from the containment assembly 125.

In one example, each of the air-cooling units may have a cooling capacity of 275 kW. Thus, two air-cooling units 122a, 122c may have a cooling capacity of 6×275 kW=1.65 MW. And each liquid-cooling system assembly may have a cooling capacity of 500 kW. Thus, the two liquid-cooling system assemblies and the two air-cooling units may have a total cooling capacity of 2×500 kW+1.65 MW=2.65 MW. Therefore, for the data center pod illustrated in FIG. 3, the two liquid cooling system assemblies and the two air-cooling units may have the capacity, for example, to cool forty server cabinets averaging 65 kW each.

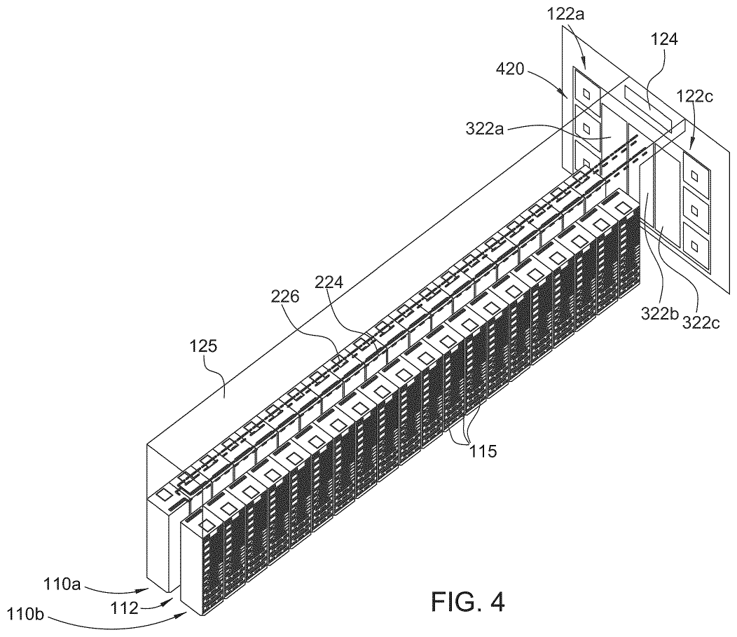

FIG. 4 illustrates another mixed air- and liquid-cooled data center pod 400, which includes a third air- and liquid-cooling system assembly. The third air- and liquid-cooling system assembly includes two air-cooling units and three liquid cooling system assemblies. The data center pod also includes two arrays of server cabinets facing away from each other and forming a hot aisle 112. While the illustrated server cabinet arrays 110a, 110b each includes twenty server cabinets 115, this disclosure contemplates server cabinet arrays including any number of server cabinets. The number of server cabinets in a server cabinet array may be limited or dictated by the cooling capacity of the third air- and liquid-cooling system assembly and the cooling requirements of the server cabinets.

A containment assembly 125 is fluidically coupled to and disposed above the hot aisle 112. The containment assembly 125 is also fluidically coupled to an aperture in an interior wall 105 of the data center building. The interior wall 105 may form a portion of an enclosure that collects heated air from the containment assembly 125 before the heated air is cooled by the two arrays of fan and heat exchanger assemblies and the three liquid cooling systems. In one aspect, the interior wall 105 and the exterior wall of the data center building may form a portion of the enclosure that collects heated air flowing from the containment assembly 125.

In one example, each of the fan and heat exchanger assemblies may have a cooling capacity of 275 kW. Thus, two air-cooling units may have a cooling capacity of 6×275 kW=1.65 MW. And each liquid cooling system assembly may have a cooling capacity of 500 kW. Thus, the three liquid cooling system assemblies and the two air-cooling units may have a total cooling capacity of 3×500 kW+1.65 MW=3.15 MW. Therefore, for the data center pod illustrated in FIG. 4, the three liquid cooling system assemblies and the two air-cooling units may have the capacity, for example, to cool forty server cabinets averaging 75 kW each.

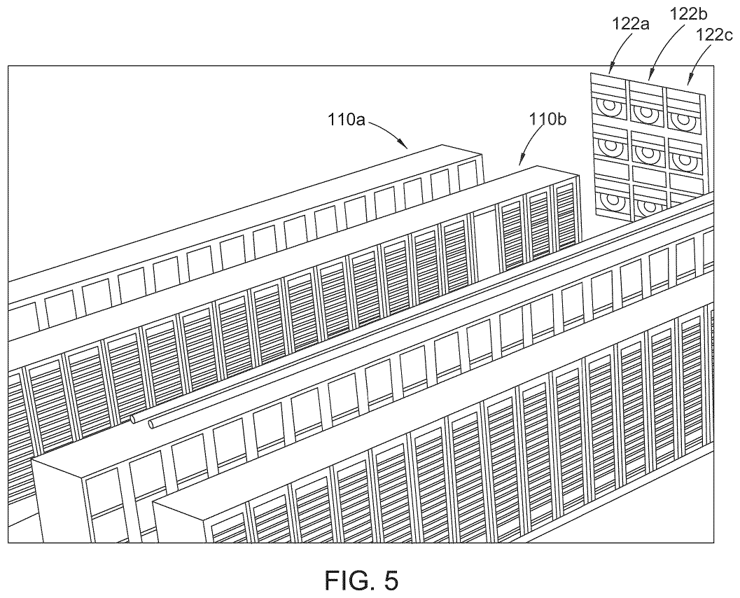

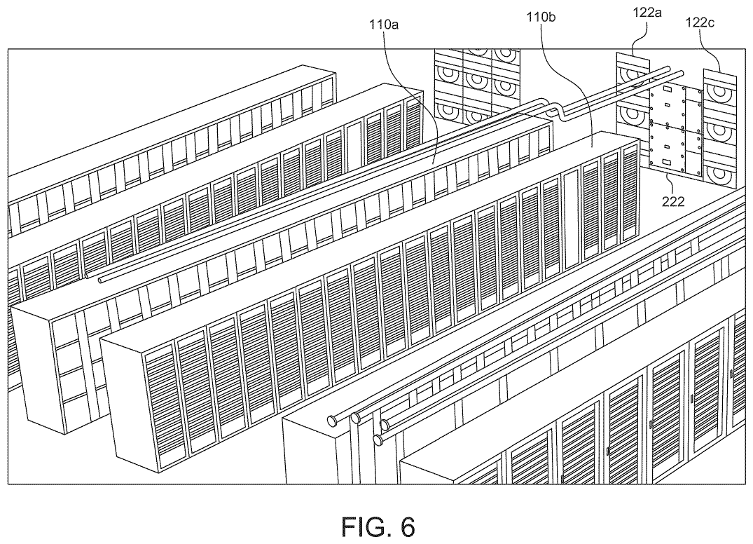

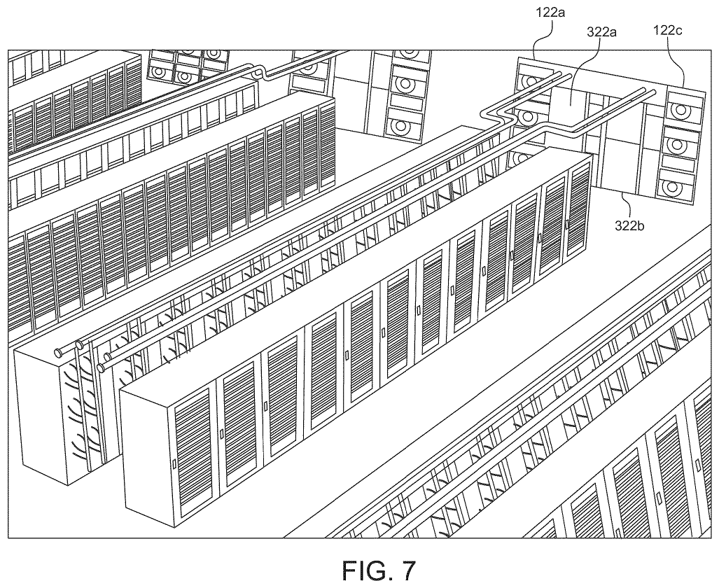

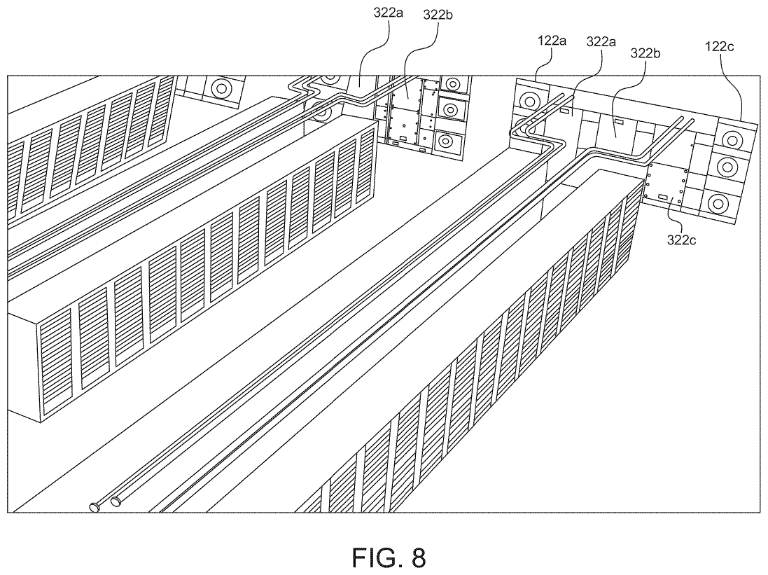

Unlike the data center pod assembly of FIG. 5, FIGS. 6-8 illustrate liquid-cooling distribution systems used in the data center pod assemblies of FIGS. 2-4, respectively. As shown in FIGS. 6-8, the liquid cooling distribution systems include horizontally extending and/or vertically extending fluid conduits. In aspects, one or more vertically extending fluid conduits may align with the backend of each server cabinet.

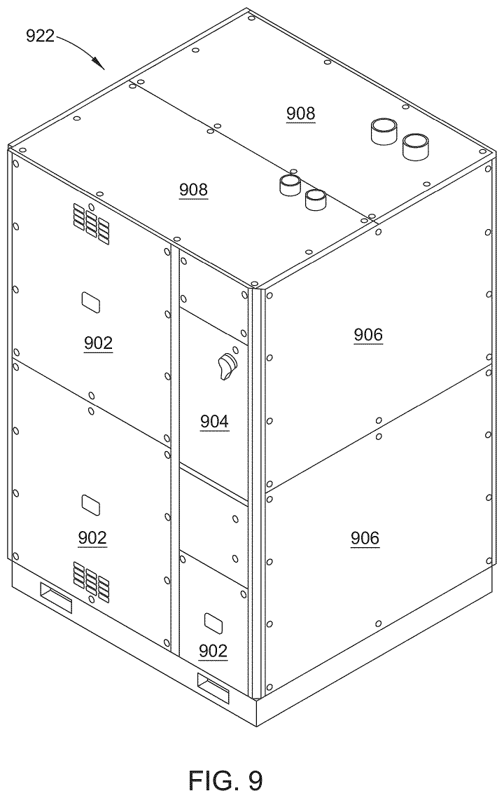

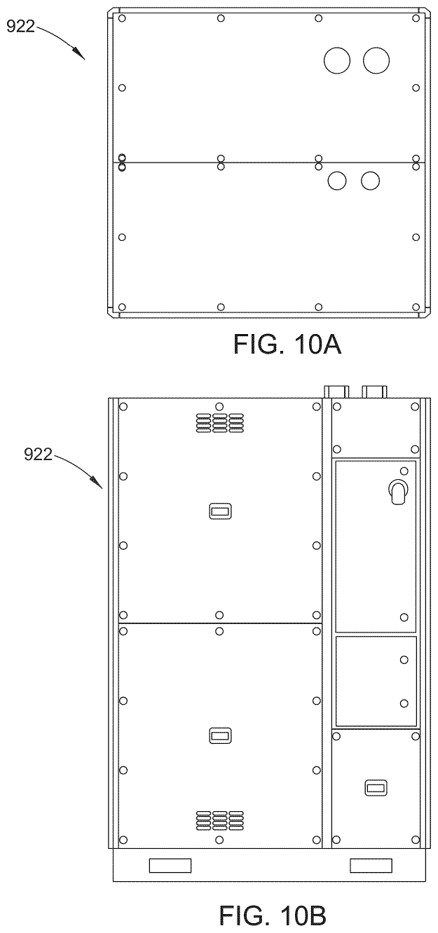

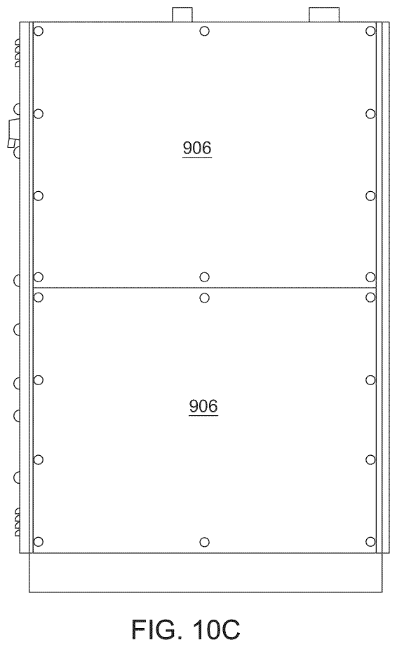

FIGS. 9, 10A-C, and 11 show different views of an example of a cooling distribution unit (CDU) 922 according to aspects of the disclosure. The CDU 922 includes an enclosure having various access doors 902, 904 and panels 906, 908. The CDU 922 includes a heat exchanger 1102 that is in fluidic communication with a liquid cooling circuit including a technology supply line 1124 and technology return line 1126, which are in fluid communication with the IT cabinets. The CDU 922 also includes a facility supply line 1114 and a facility return line 1116 in fluidic communication with the heat exchanger 1102. The heat exchanger 1102 causes heat to transfer from the technology fluid circuit, which includes the technology supply line 1124 and technology return line 1126, to the facility fluid circuit, which includes the facility supply line 1114 and the facility return line 1116.

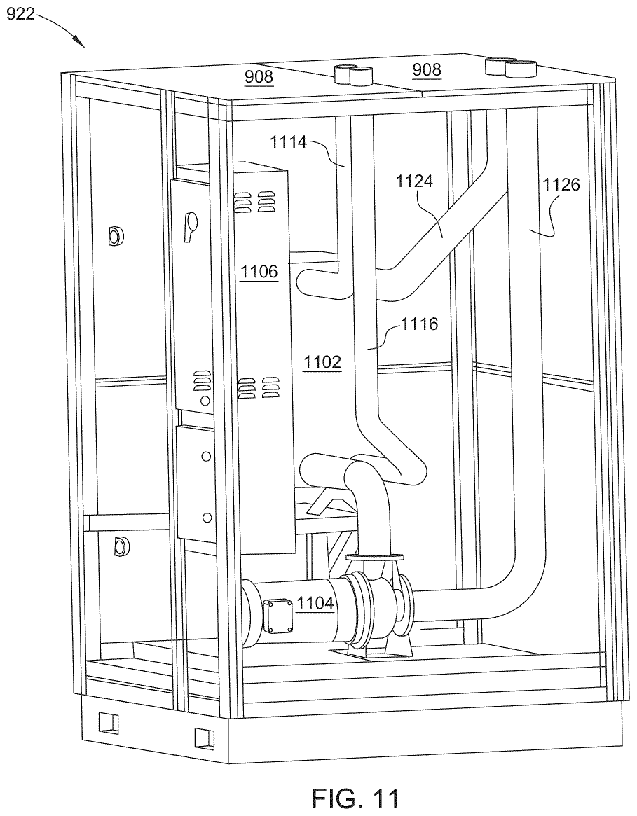

As shown in FIG. 11, the facility supply line 1114, the facility return line 1116, the technology supply line 1124, and the technology return line 1126 pass through the top panels 908 of the CDU 922. This enables simple and seamless connections to the technology fluid loop and the facility fluid loop, in the case where the technology fluid loop and the facility fluid loop are disposed above and/or near the top of the CDU 922. In other aspects, all or a portion of the facility supply line 1114, the facility return line 1116, the technology supply line 1124, and the technology return line 1126 may pass through one or more other panels, e.g., a side panel 906 or a bottom panel (not shown) of the CDU 922.

All or a portion of the facility supply line 1114, the facility return line 1116, the technology supply line 1124, and the technology return line 1126 may pass through one or more other panels in cases where the technology fluid loop and the facility fluid loop are disposed near other panels of the CDU 922. For example, if the technology fluid loop and/or the facility fluid loop are disposed below a subfloor of the data center facility, the facility supply line 1114, the facility return line 1116, the technology supply line 1124, and the technology return line 1126 may pass through one or more bottom or side panels, e.g., side panel 906, of the CDU 922.

The CDU 922 also includes a liquid pump 1104, which is fluidically coupled to the return line 1126 and which is in fluid communication with the heat exchanger 1102. The liquid pump 1104 may be a water pump or other pump suitable for pumping a liquid through the liquid cooling circuit. The CDU 922 also includes an electrical panel 1106 electrically coupled to the liquid pump 1104. The electrical panel 1106 may be accessed using electrical access door 904, for example, enabling a person to perform repairs or maintenance.

The electrical panel 1106 may include a transfer switch that switches between power feeds. One of the power feeds may be electrically coupled to an electrical generator, e.g., a diesel generator. The transfer switch may automatically switch to the power feed electrically coupled to the electrical generator in the event of a power failure. The electrical panel 1106 may include a control panel operationally coupled to the liquid pump 1104, or other pump suitable for pumping a fluid, e.g., a fluid in the liquid state.

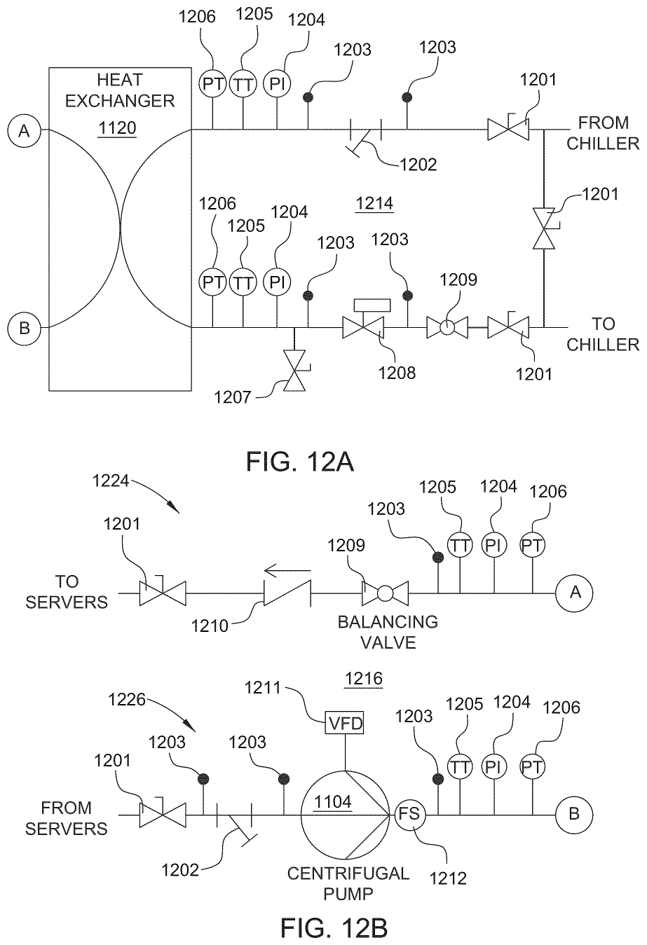

The CDU 922 may also include a strainer, e.g., the strainer 1202 symbolically depicted in FIG. 12B, in fluid communication with the liquid pump 1104. The strainer removes or filters particulate matter and debris from the coolant liquid to maintain the efficiency and longevity of the CDU 922 and other components of the data center cooling system.

The CDU 922 may incorporate all or a portion of the fluid circuits illustrated in FIGS. 12A and 12B, which form part of the overall information technology (IT) cooling system of the disclosure. FIG. 12A is a schematic diagram of a facility-side fluid circuit or a facility fluid circuit 1214. The facility fluid circuit 1214 includes a supply portion receiving cooling fluid from a facility fluid loop, e.g., a chiller fluid loop, and a return portion returning heated fluid to the facility fluid loop.

The supply portion of the facility fluid circuit 1214 may include an isolation valve 1201 and a strainer 1202 downstream from the isolation valve 1201. The isolation valve 1201 may be a butterfly valve or any fluid valve suitable for isolating the facility fluid circuit 1214, for example, to allow for maintenance of one or more components of the facility fluid circuit 1214. The strainer 1202 removes or filters particulate matter and debris from the coolant liquid flowing through the supply portion of the facility fluid circuit 1214 to maintain the efficiency and longevity of the CDU 922 and other components of the data center cooling system.

The supply portion of the facility fluid circuit 1214 may also include Pete's plugs 1203 on both sides of the strainer 1202. The Pete's plugs 1203 may be small, threaded access points that allow for pressure or temperature readings without the need for system shutdown. The Pete's plugs 1203 may include a self-sealing valve that prevents coolant from leaking when inserting or removing a pressure or temperature transducer probe to or from the Pete's plugs 1203. The supply portion of the facility fluid circuit 1214 may also include a pressure indicator (PI) 1204, a temperature thermistor (TT) 1205, and a pressure transmitter (PT) 1206. The PI 1204, the TT 1205, and the PT 1206 may be disposed downstream from the strainer 1202 or may be disposed at other positions on the supply portion of the facility fluid circuit 1214.

The return portion of the facility fluid circuit 1214 may include a drain 1207 and a pressure independent control valve (PICV) 1208 downstream from the drain 1207. The drain 1207 may be used to remove, for example, contaminants or condensation that accumulates in the facility fluid circuit 1214. This may ensure proper functionality of the cooling system, prevent waterlogging, and aid in flushing and/or cleaning the facility fluid circuit 1214. The PICV 1208 regulates the flow of the fluid flowing through the return portion of the facility fluid circuit 1214 by maintaining consistent flow regardless of pressure fluctuations. The PICV 1208 may include a flow-regulating component, a pressure control diaphragm, and an actuator for making precise adjustments.

The return portion of the facility fluid circuit 1214 may also include a PI 1204, a TT 1205, and a PT 1206a, disposed upstream from the drain 1207. In other aspects, the PI 1204, the TT 1205, and the PT 1206 may be disposed at other positions on the return portion of the facility fluid circuit 1214. The return portion of the facility fluid circuit 1214 may also include Pete's plugs 1203 on both sides of the PICV 1208.

The return portion of the facility fluid circuit 1214 may also include a balancing valve 1209 downstream from the PICV 1208 and an isolation valve 1201 downstream from the balancing valve 1209. The balancing valve 1209 ensures that fluid is evenly distributed across all fluid circuits, thereby preventing under-supply or over-supply to any specific portion of the data center cooling system. The balancing valve 1209 may include a flow-regulating feature, e.g., a calibrated dial or scale, a valve body for directing fluid flow, and ports for measuring differential pressure or flow rate. In operation, the balancing valve 1209 adjusts the fluid flow resistance to balance the hydraulic load among parallel branches of the data center cooling system.

FIGS. 12B is a schematic diagram of a technology-side fluid circuit or a technology fluid circuit 1216. The technology fluid circuit 1216 includes a supply portion 1224 feeding cooling fluid to the IT cabinets and a return portion 1226 receiving heated fluid from the IT cabinets. The supply portion 1224 may include a balancing valve 1209 and a Pete's plug 1203 disposed upstream from the balancing valve 1209. The supply portion 1224 may also include a PI 1204, a TT 1205, and a PT 1206 disposed upstream from the Pete's plug 1203. In other aspects, one or more PIs 1204, TTs 1205, and/or PTs 1206 may be disposed at other positions on the supply portion 1224.

The supply portion 1224 may also include a check valve 1210 downstream of the balancing valve 1209 and an isolation valve 1201 downstream of the check valve 1210. The check valve 1210 ensures unidirectional flow of the cooling fluid to the IT cabinets and prevents backflow that could disrupt the cooling system's efficiency and compromise temperature regulation. By maintaining unidirectional flow of the cooling fluid, the check valve safeguards cooling system components, such as heat exchangers and pumps, from pressure fluctuations and damage caused by reverse flow.

The return portion 1226 may include an isolation valve 1201 and a strainer 1202 downstream from the isolation valve 1201. The return portion 1226 may also include Pete's plugs 1203 on both sides of the strainer 1202. The return portion 1226 may also include a fluid pump 1104, e.g., a centrifugal pump, downstream from the strainer 1202. The return portion 1226 may also include a variable frequency drive 1211 coupled to the fluid pump 1104 and configured to control the speed of the fluid pump 1104. The return portion 1226 may also include a flow switch 1212 downstream from the fluid pump 1104. The return portion 1226 may also include a Pete's plug 1203 and a PI 1204, a TT 1205, and a PT 1206 disposed downstream from the Pete's plug 1203.

As illustrated in FIGS. 12A and 12B, the technology fluid circuit 1216 is thermally coupled to the facility fluid circuit 1214 through the heat exchanger 1102, which enables heat transfer from the technology fluid circuit 1216 to the facility fluid circuit 1214.

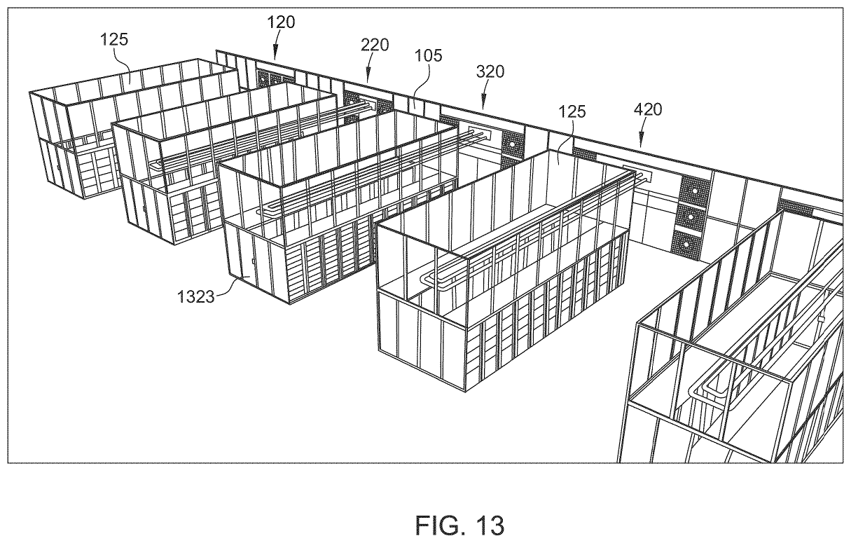

FIG. 13 is a perspective view of data center pod assemblies coupled to various air and/or liquid cooling system assemblies. The various air and/or liquid cooling system assemblies may support shifting cooling requirements with scalable cooling technologies. A data center pod assembly may include a containment assembly 125 disposed above a hot aisle 112 formed by two rows of IT equipment cabinets. The hot aisle 112 may be enclosed on one side by doors 1323, which enable access to the backend of the IT equipment cabinets. In one aspect, a data center pod assembly may be coupled to only a liquid cooling system assembly, in which case the data center pod assembly may not include a containment assembly 125. In aspects, the supply and return lines may be metal piping, e.g., copper piping, and may be disposed within the containment assembly 125.

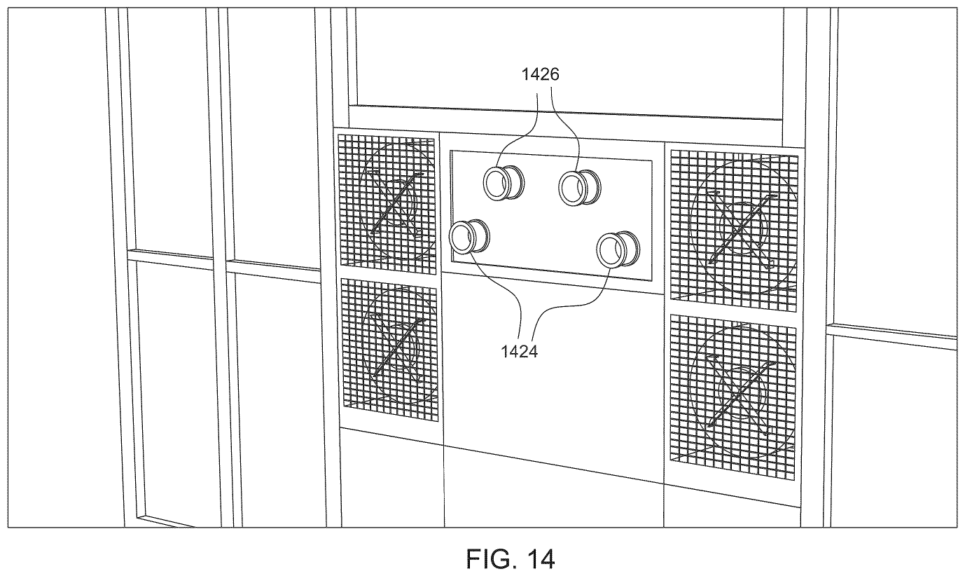

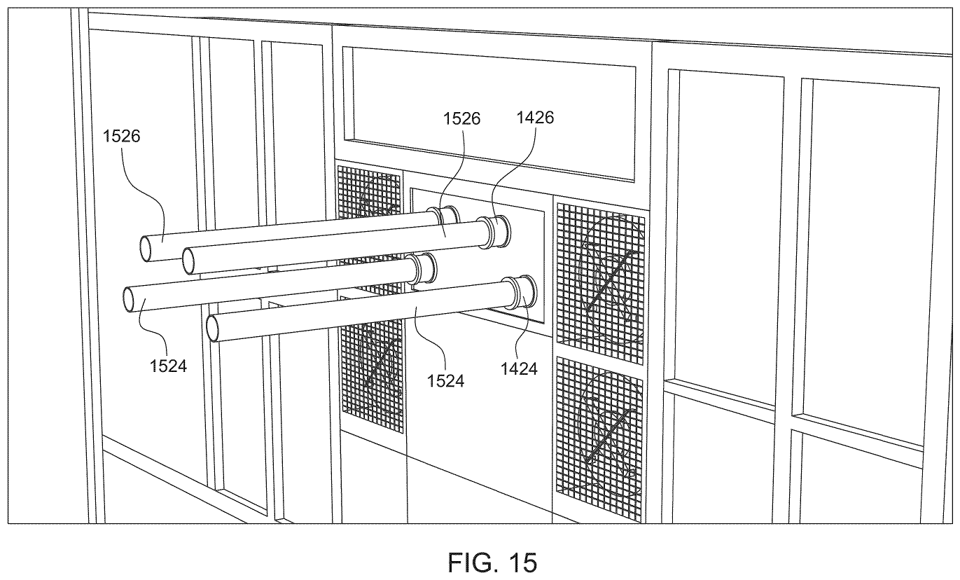

FIG. 14 illustrates an example of an air- and liquid-cooling system assembly. The CDU of the air- and liquid-cooling system assembly may include two or more coupling members, e.g., connectors or fittings, for coupling to supply and return lines or piping of a data center pod assembly. For example, the CDU of FIG. 14 includes four coupling members: two supply coupling members 1424 for coupling to supply lines or piping of a data center pod assembly and two return coupling members 1426 for coupling to return lines or piping of the data center pod assembly. FIG. 15 illustrates an air- and liquid-cooling system assembly coupled to supply lines 1524 and return lines 1526 via the supply coupling members 1424 and return coupling members 1426, respectively. In aspects, the coupling members 1424, 1426 may include bulkhead fittings or quick-connect fittings to facilitate quick installation of the CDU.

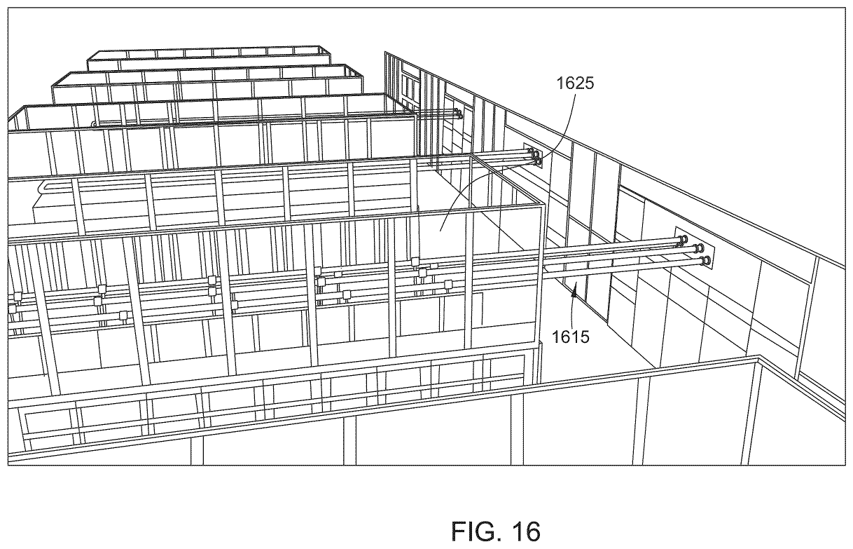

FIG. 16 illustrates data center pod assemblies coupled to air and/or liquid cooling systems via supply and return lines or pipes 1615 disposed above each of the hot aisles in the air containment assemblies 1625. The supply and return lines or pipes may be supply and return header lines or pipes. The supply header lines may be coupled to branch supply lines, which, in turn, may be coupled to the IT equipment cabinets, respectively. In this way, cooling liquid may be distributed to one or more IT equipment cabinets. And the return header lines may be fluidically coupled to branch return lines, which, in turn, are fluidically coupled to IT equipment cabinets, respectively. In operation, the cooling liquid is heated by the IT equipment, e.g., computer systems and/or processors, residing in the IT equipment cabinets and returned to the liquid cooling systems via the branch return lines and the return header lines.

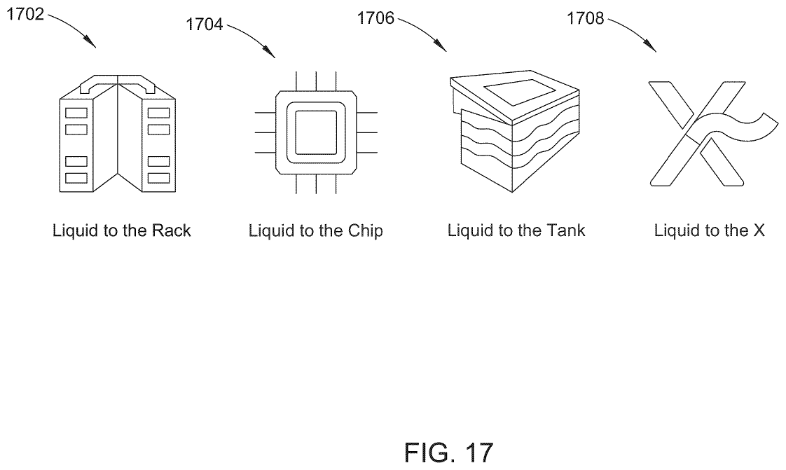

FIG. 17 illustrates examples of various liquid cooling technologies. In some aspects, the systems and methods of this disclosure may provide a scalable, universal architecture that can support diverse liquid cooling technologies. The liquid cooling technologies may include liquid to the rack 1702, liquid to the chip 1704, liquid to the tank 1706, and/or liquid to the X 1708.

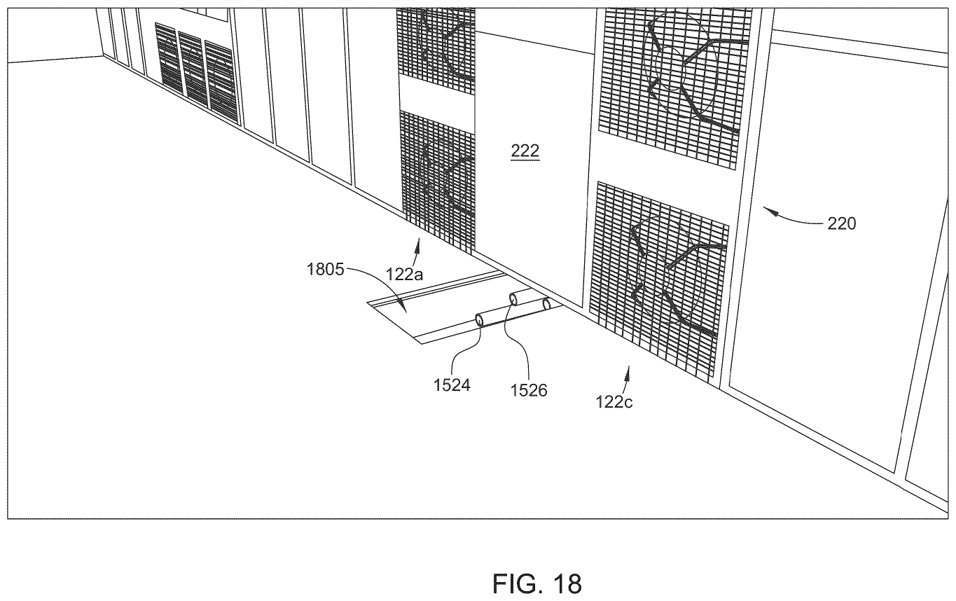

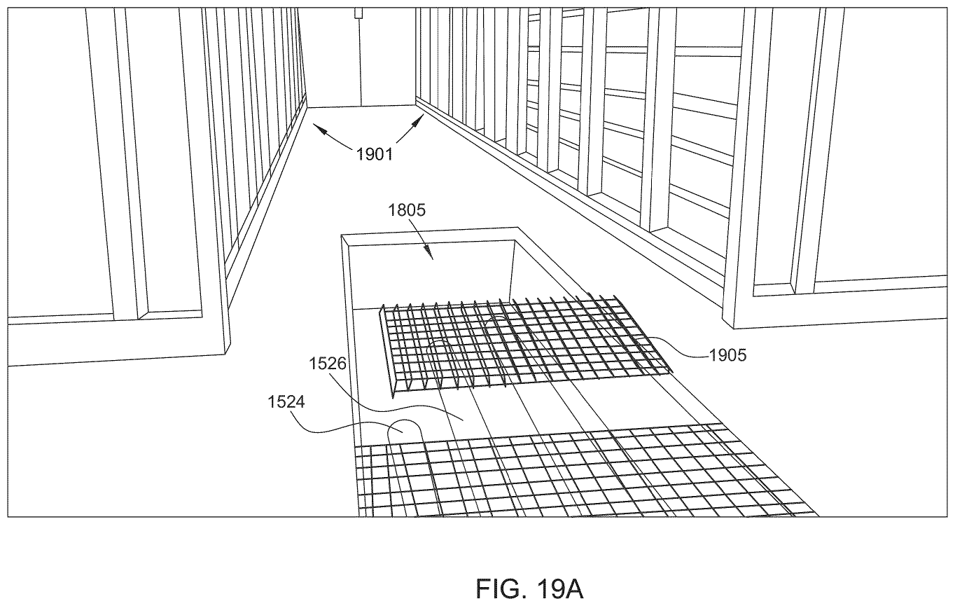

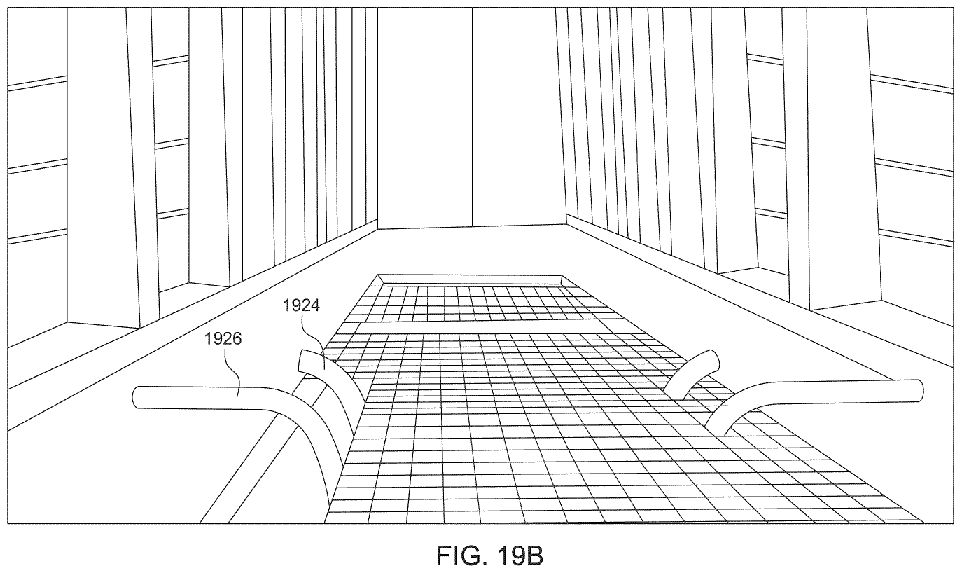

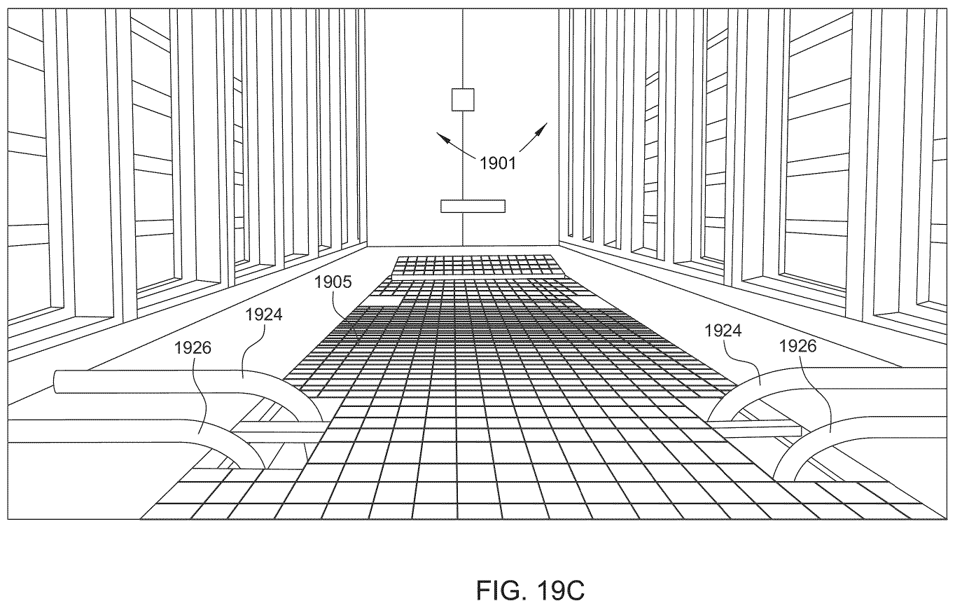

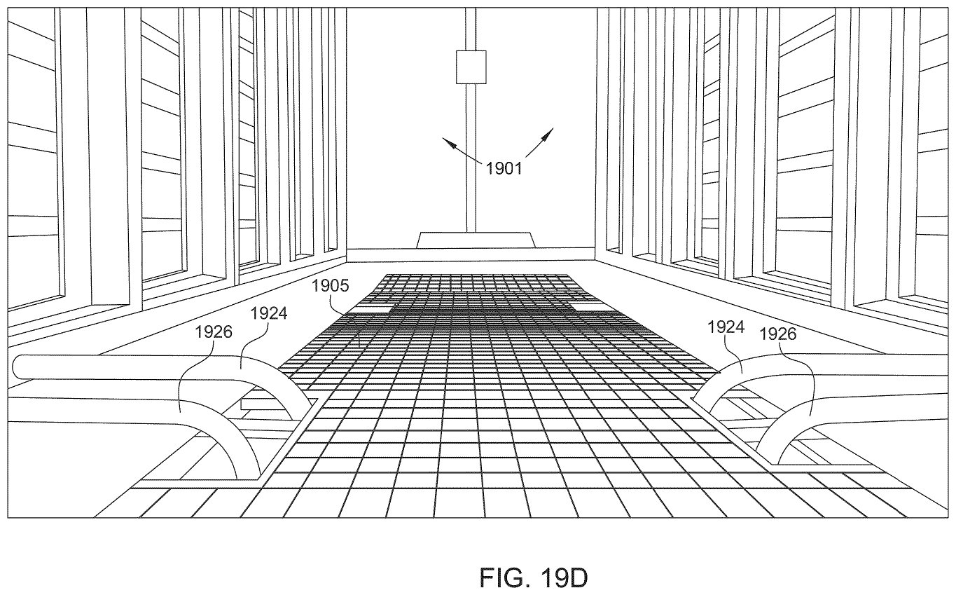

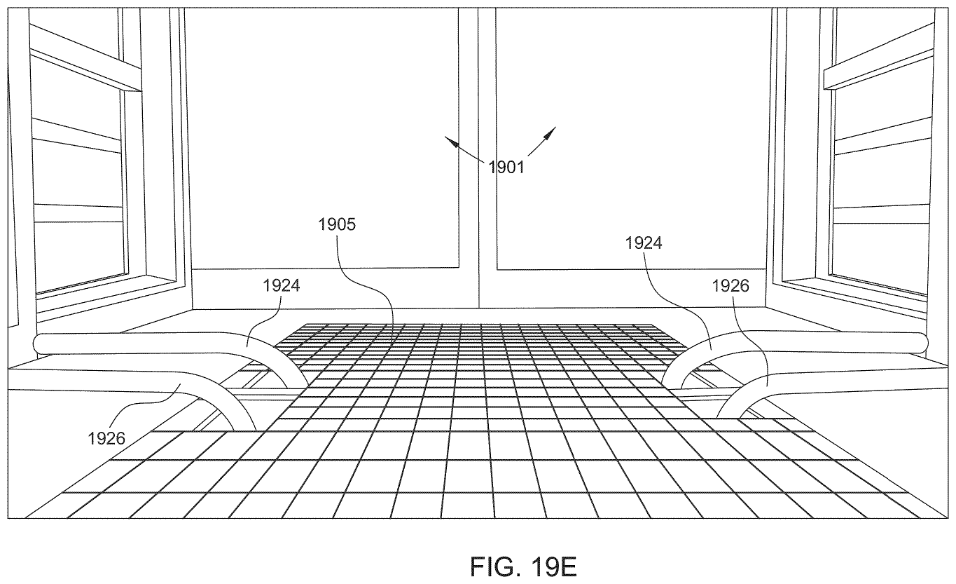

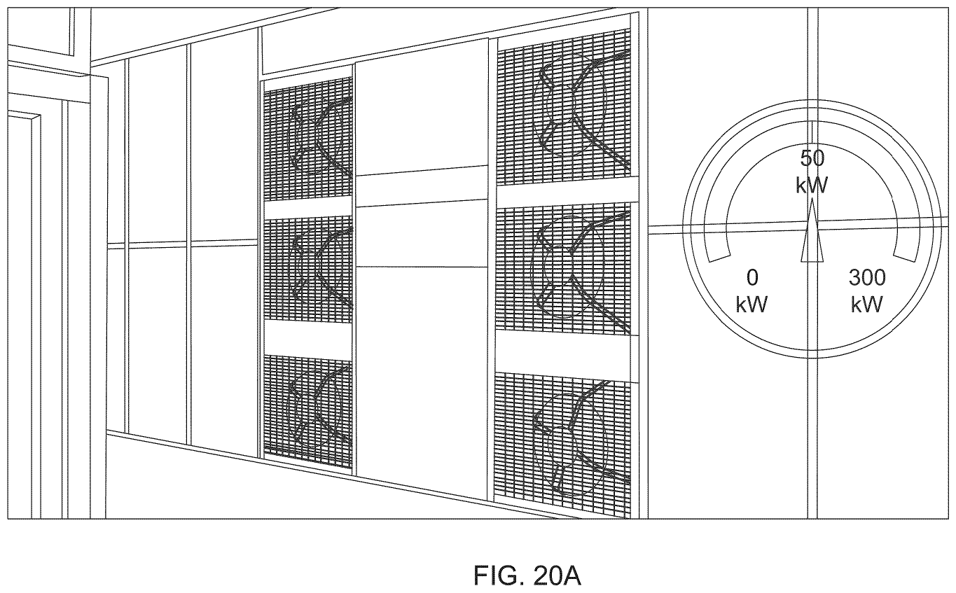

Additionally, or alternatively, as illustrated in FIG. 18, a coolant distribution unit 222, which may be positioned between air-cooling units 122a, 122c of an air- and liquid-cooling system 220, may be coupled to supply lines 1524 and return lines 1526 deployed in a subfloor volume 1805 of a data center facility. As illustrated in FIGS. 19A-19E, the supply lines 1524 and return lines 1526 may be positioned in and along a subfloor volume 1805 of a hot aisle 112 and coupled to supply branch lines and return branch lines to and from IT equipment cabinets 1901. The supply lines 1524 and return lines 1526 disposed in the subfloor volume 1805 of the hot aisle 112 may be accessed via removable grate structures 1905 or other structures suitable for allowing a person to safely traverse the hot aisle 112 while also allowing access to the supply lines 1524 and return lines 1526 disposed in the subfloor volume 1805 of the hot aisle 112. The supply branch lines 1924 and the return branch lines 1926 may be implemented with flexible conduits. The flexible conduits may include one or more of flexible PVC piping, cross-linked polyethylene (PEX) tubing, corrugated stainless steel tubing (CSST), or reinforced rubber hose.

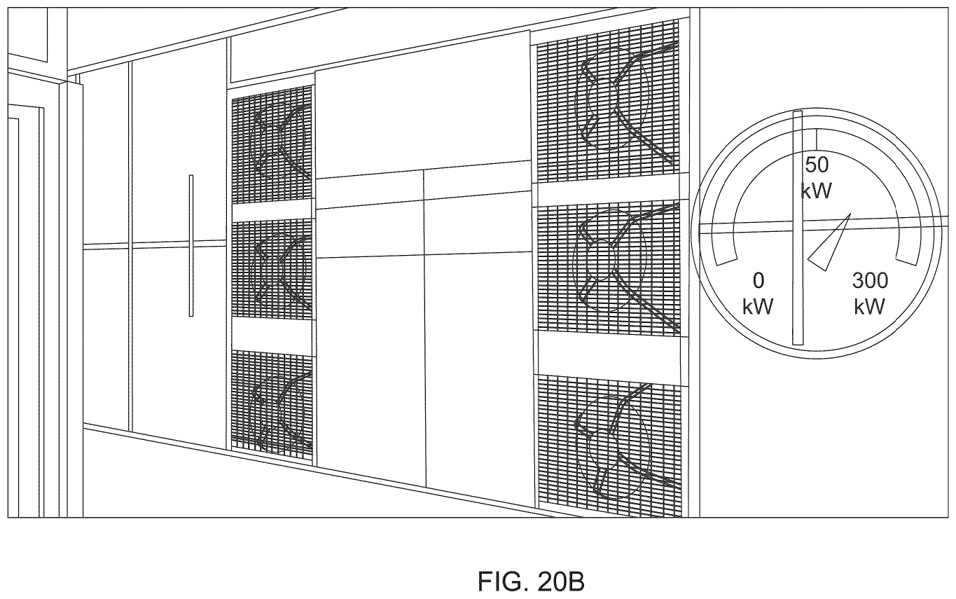

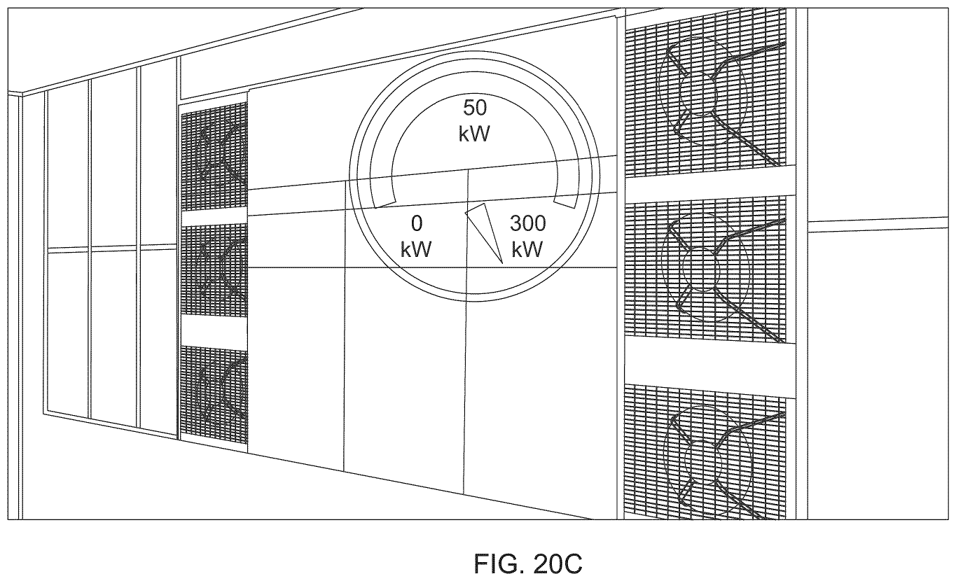

FIGS. 20A-20C illustrate an example of a flexible cooling technique, which solves various capacity and/or density challenges. FIGS. 20A-20C illustrate expansion from a first air- and liquid-cooling system assembly to a second air- and liquid-cooling system assembly with greater cooling capacity than the first air- and liquid-cooling system assembly.

FIGS. 21A and 21B illustrate a data center pod designed for a mixed-cooled environment. In the example illustrated in FIGS. 21A and 21B, the data center pod may be a 2 MW data center pod configured for 70% liquid cooling and 30% air cooling. In aspects, the data center pod may be configured for a spectrum of powers and other liquid-to-air ratios. The data center pod 2100 includes two server rack sub-pods 2101a, 2101b, which reside in the data hall 2102. Each of the server rack sub-pods 2101a, 2101b includes two rows or arrays of server racks 110a, 110b forming a hot aisle 112. In the example of FIG. 21, each row of server racks 110a, 110b includes both liquid-cooled server racks 2110 and air-cooled server racks 2111. Each of the server rack sub-pods 2101a, 2101b may include air containment assemblies 2125a, 2125b fluidically coupled to the hot aisles 112. The air containment assemblies 2125a, 2125b may be coupled to or supported by the drop ceiling 2106. That data center pod 2100 may also include a cable tray assembly 2115, which supports cables of the server racks 2110, 2111. The configuration of FIGS. 21A and 21B integrates into the overall data center chilled water loop 2134, 2136, which may reside within the gallery 2104.

The data center pod includes air-cooling units 122a-122e and CDUs 322a-322e, which may reside within a gallery 2104 formed by an the interior wall 105 and the exterior wall 2105. In aspects, the data center pod 2100 may include any number of air-cooling units 122a-122e and CDUs 322a-322e to meet the cooling needs of the liquid-cooled server racks 2210 and the air-cooled server racks 2111. Each of the liquid-cooled server racks 2110 is fluidically coupled to a technology liquid supply loop 224 and a technology liquid return loop 226 through branch liquid supply piping 2124 and branch liquid return piping 2126, respectively.

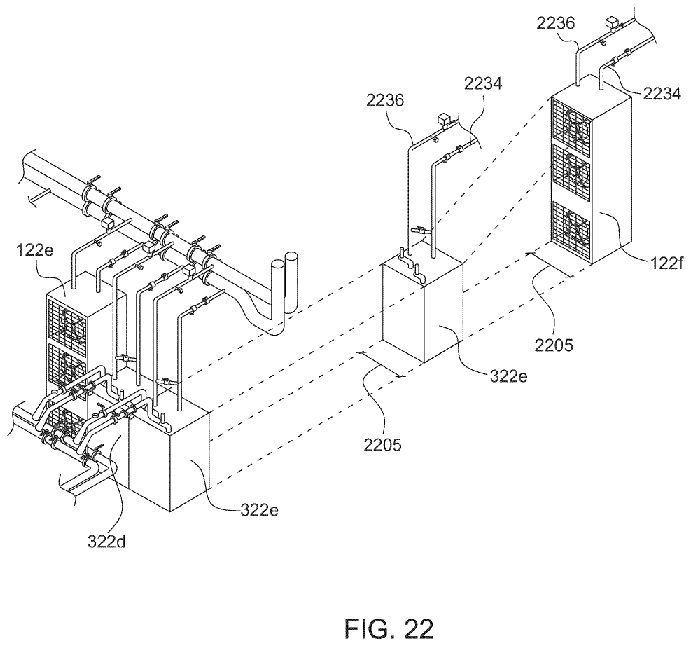

FIG. 22 depicts the interchangeability between a CDU 322e and an air-cooling unit 122e, each of which may be seamlessly coupled to the same chilled water loops 2134, 2136 via branch supply lines 2234 and branch return lines 2236. The CDUs, e.g., CDU 322e, and the air-cooling units, e.g., air-cooling unit 122e, may be designed with the same or substantially the same width 2205 such that the air-cooling unit 122f can be easily and seamlessly replaced with a CDU 322e or, as depicted in FIG. 22, the CDU 322e can be easily and seamlessly replaced with the air-cooling unit 122f. This feature allows for flexibility in adjusting to changes to the number and types of server racks in a data center pod, thereby adjusting to clients' needs seamlessly.

Additionally, or alternatively, CDUs and air-cooling units may be designed such that one or more other dimensions of the CDUs and the air-cooling units are the same or substantially the same. For example, the height of the CDUs may be the same or substantially the same as the height of the air-cooling units. Accordingly, the same connection lines fluidically connecting the air-cooling units to the chilled water loop could be used to connect the CDUs to the chilled water loop (and vice versa) with little or no modification to the connection lines. As another example, the depth of the CDUs may be the same or substantially the same as the depth of the air-cooling units. In aspects, if at least the height of a CDU and a fan and heat exchanger assembly are the same or substantially the same, the CDU connectors to the connection lines may have at least the same or substantially the same spacing as the fan and heat exchanger connectors. This uniformity in dimensions supports a streamlined setup, making it easy to scale or modify the cooling system of the data center pod as cooling needs evolve, e.g., increase or decrease.

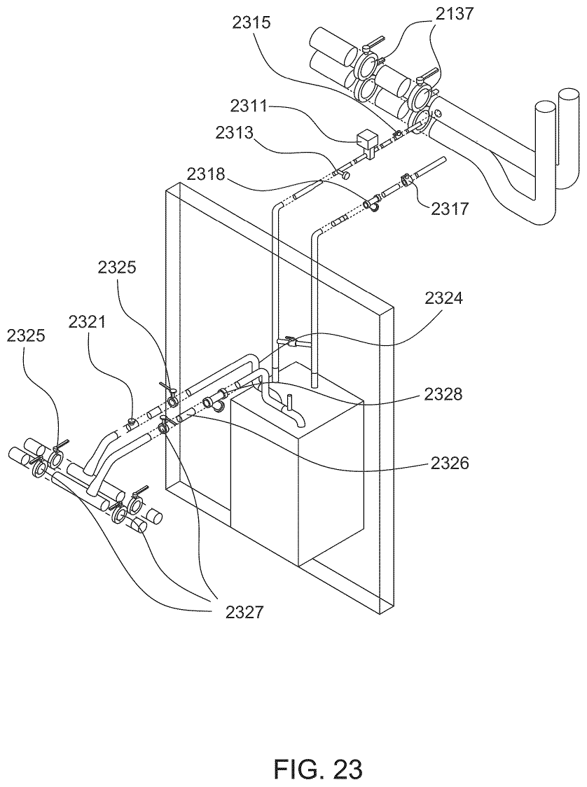

FIG. 23 illustrates the CDU piping features within the data center's cooling system, including various control and isolation features for effective operation and maintenance. Butterfly valves 2135, 2137 are coupled to respective supply and return chilled water loops 2134, 2136. The butterfly valves 2135, 2137 allow for isolation during maintenance, ensuring that sections of the system can be serviced without interrupting overall functionality and operation of the data center cooling system. Ball valves 2315, 2317 are coupled to chilled water loop connection supply and return lines 2314, 2316, respectively. Also, a motor control valve 2311 and a balancing valve 2313 are coupled to the return line 2316 to manage flow and pressure.

For added filtration and protection, a strainer 2318 is coupled to the chilled water loop connection supply line 2314. The CDU piping features also include a strainer 2328 on the technology liquid loop connection return line 2326, preventing contaminants from circulating through the cooling system. Additionally, automatic control valves 2321 are coupled to the return line to enable automated adjustments as needed. Butterfly valves 2325, 2327 are coupled to respective supply and return chilled water loops 2324, 2326. The butterfly valves 2325, 2327 allow for isolation during maintenance, ensuring that sections of the system can be serviced without interrupting overall functionality and operation of the data center cooling system.

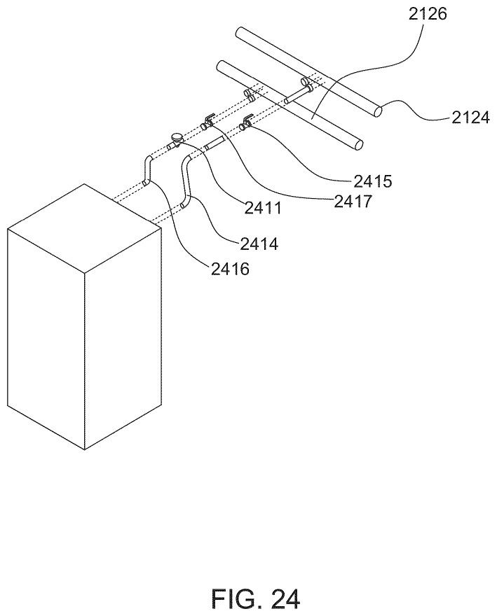

FIG. 24 illustrates the side connection compatibility of the data center cooling system, enabling flexible integration within the data center infrastructure. This setup includes pipe taps 2404, 2406 on the technology liquid branch supply and return lines 2124, 2126 for easy access and maintenance. Ball valves 2415, 2417 are coupled to technology liquid branch supply and return connection lines 2414, 2416, respectively, allowing for the isolation of liquid-cooled server racks, e.g., liquid-cooled server rack 2110, as needed.

Automatic control valves 2411 are coupled to the technology liquid branch return connection line 2416 to streamline flow management. In aspects, technology liquid branch supply and return connection lines 2414, 2416 may be flexible lines, e.g., pipes or hoses, to support direct side connections, making the cooling system adaptable to various configurations without the need for extensive adjustments.

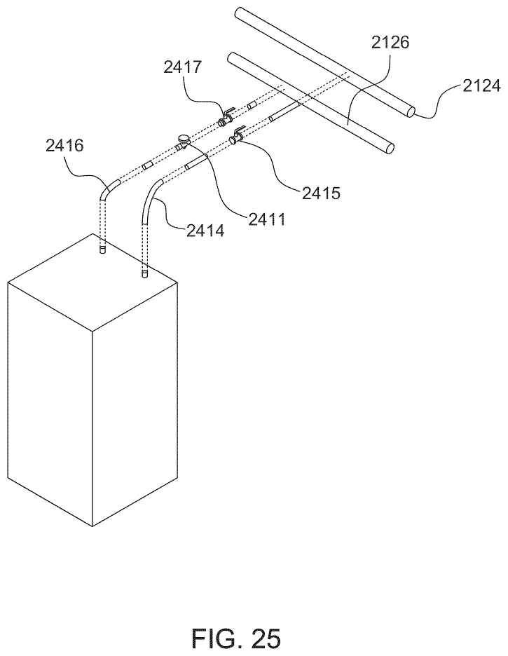

FIG. 25 illustrates a top connection compatibility of the cooling system, designed to integrate seamlessly within the data center's infrastructure. The cooling system features technology liquid branch supply and return lines 2124, 2126 coupled to the top portion of a liquid-cooled server rack, e.g., the liquid-cooled server rack 2110 of FIG. 21. Ball valves 2415, 2417 are coupled to the technology liquid branch supply and return connection lines 2414, 2416, respectively, to allow for the isolation of liquid-cooled server racks, e.g., the liquid-cooled server rack 2110 of FIG. 21, facilitating maintenance and control over individual sections.

The cooling system also includes automatic control valves 2411 coupled to the technology liquid branch return connection line 2416 to regulate flow as needed. For added flexibility, the technology liquid branch supply and return lines 2124, 2126 may be flexible lines, e.g., flexible pipes or hoses, enabling direct top-side connections to the liquid-cooled server rack. This enhances adaptability and makes the cooling system compatible with a variety of configurations without needing significant modifications.

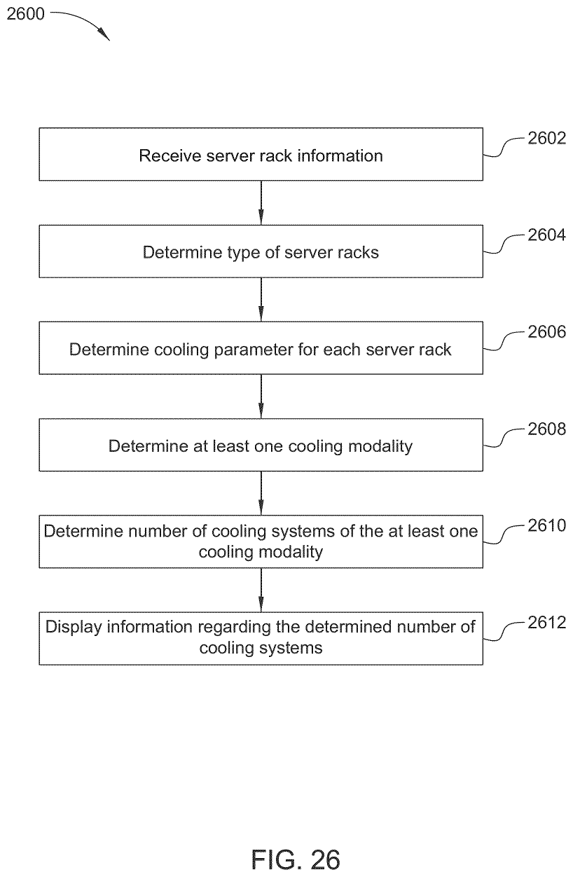

FIG. 26 is a flow chart illustrating a method 2600 of designing a data center cooling system. The method 2600 may be implemented by design or planning computer applications. The computer applications may include an interactive interface allowing an operator to interact with features of the computer applications to design a data center including the cooling system.

According to the method 2600, initially, server rack information is received at block 2602. The server rack information may include the types of server racks, e.g., air-cooled server racks and/or liquid-cooled server racks, the power requirements of the server racks, and the cooling requirements of the server racks. Using this information, the method 2600 determines the types of server racks at block 2604.

Next, the method 2600 determines cooling parameters specific to each of the server racks at block 2606. These cooling parameters may include optimal airflow, target temperature ranges, and any other specifications necessary for effective cooling. The method 2600 then determines at least one cooling modality to be employed based on the determined types of server racks and the determined cooling parameters for each of the server racks at block 2608. The at least one cooling modality may include a gas-cooling modality or a liquid-cooling modality. For example, the gas-cooling modality may involve an air-cooling modality, while liquid-cooling modality may involve a water-cooling modality or a refrigerant-cooling modality.

Once the cooling modality is determined, the method 2600 determines the number of cooling systems of the at least one cooling modality based on the cooling parameters for each of the server racks at block 2610. For the gas-cooling modality, the method 2600 may determine number of air-cooling units or a number of fan and heat exchanger modules in the air-cooling units. For the liquid-cooling modality, the method 2600 may determine the number of coolant distribution units required to efficiently supply the cooling fluid to the designated server racks.

In cases where both gas-cooling and liquid-cooling modalities are utilized, the method 2600 may determine an arrangement of gas-cooled server racks and liquid-cooled server racks. This arrangement may, for example, position gas-cooled server racks between liquid-cooled server racks, which may optimize thermal balance and cooling efficiency.

The method 2600 may also determine a number of data center pods to be deployed based on the cooling parameters for each of the server racks. The method 2600 may also determine types of data center pods for the data center. The types of data center pods may include gas-cooled data center pods, liquid-cooled data center pods, and/or hybrid gas- and liquid-cooled data center pods. The determination of the number and/or types of data center pods facilitates a modular approach to data center design.

Lastly, the method 2600 displays the results at block 2612, providing the user with information regarding the determined cooling modalities and the number and arrangement of cooling systems. This may allow for a user to validate or adjust the cooling system design. In aspects, a graphical representation of the arrangement of cooling systems in the data center pod may be displayed to the user.

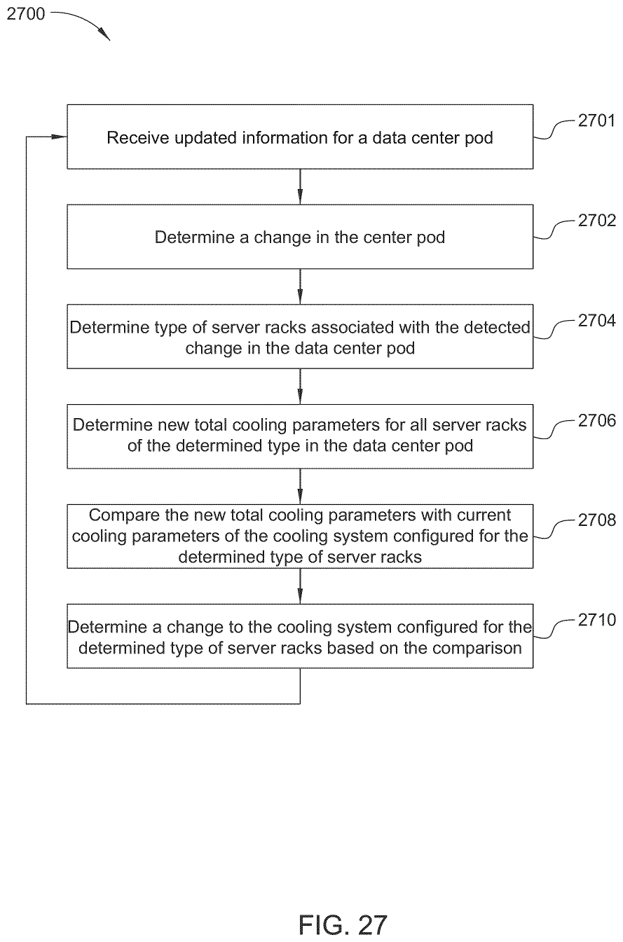

FIG. 27 is a flow chart illustrating a method of managing a data center cooling system. The method 2700 begins at block 2701 by receiving updated information for a data center pod. This initial block 2701 may involve gathering updated data about changes to IT equipment cabinets and server racks in a data center pod, including changes to the number and/or type of server racks in the data center pod. The updated information may include a client's proposal to add servers configured for high-performance computing (HPC) and/or to replace existing servers with servers configured for high-performance computing (HPC). The updated information may include parameters such as server load, thermal output, or physical alterations to the server racks.

At block 2702, based on the updated information, the method 2700 proceeds to determine a change in the data center pod. This determination may involve identifying modifications, such as the adding or removing servers or server racks, changes in server activity, or adjustments to rack-level hardware that impact cooling requirements.

At block 2704, the method 2700 determines the type of server racks associated with the detected change in the data center pod. The type of server racks may be air-cooled server racks or liquid-cooled server racks.

At block 2706, the method 2700 determines new total cooling parameters for all server racks of the determined type in the data center pod. These cooling parameters may include thermal output or cooling capacities specific to each server rack. For example, if certain server racks are going to have increased thermal output because of the addition of servers with high-performance computing capabilities, block 2706 ensures that the cooling demands of those server racks are accurately assessed and.

At block 2708, once the new total cooling parameters are determined, the method 2700 compares the new total cooling parameters with the current cooling parameters of the cooling system configured for the determined type of server racks. This comparison evaluates the capability of the current cooling system configured for the determined type of server racks to meet the new total cooling demands of the server racks.

At block 2710, based on the comparison, the method 2700 determines a change to the cooling system configured for the determined type of server racks to address the results of the comparison. This change may include replacing or augmenting the existing cooling system with a cooling system of a different cooling modality. For instance, the method 2700 may determine to replace an air-cooling unit with a coolant distribution unit (CDU) to better handle the updated cooling demands. In some cases, the width of the new CDU may be the same as or substantially similar to the width of the replaced air-cooling unit, facilitating a seamless physical transition. Alternatively, the method 2700 may determine to replace a CDU with an air-cooling unit depending on the change in the type of some server racks. For example, in a data pod, at least some liquid-cooled server racks may be replaced by air-cooled server racks, which may require at least one more air-cooling unit.

In scenarios where the current cooling modality is insufficient, the method 2700 may determine to add a different cooling modality to the cooling system. This may involve incorporating a gas-cooling modality, such as an air-cooling system, or a liquid-cooling modality, such as a water-cooling or refrigerant cooling system. In some implementations, the method 2700 may determine to adopt both gas- and liquid-cooling modalities, thereby configuring the data center to utilize hybrid cooling systems for enhanced efficiency. This may involve arranging gas-cooled server racks between liquid-cooled server racks to optimize airflow and cooling effectiveness.

The method 2700 may determine the number of CDUs and/or air-cooling units to add to or replace in the cooling system to meet the updated cooling parameters. Accordingly, the method 2700 ensures that the cooling system can adapt dynamically to changes in server rack configuration or operational demands.

In aspects, the method 2700 may include displaying a user interface indicating the change to the cooling system. For example, the method 2700 may present a user interface displaying a graphical representation of a new arrangement of at least one of CDUs, air-cooling units, or server racks.

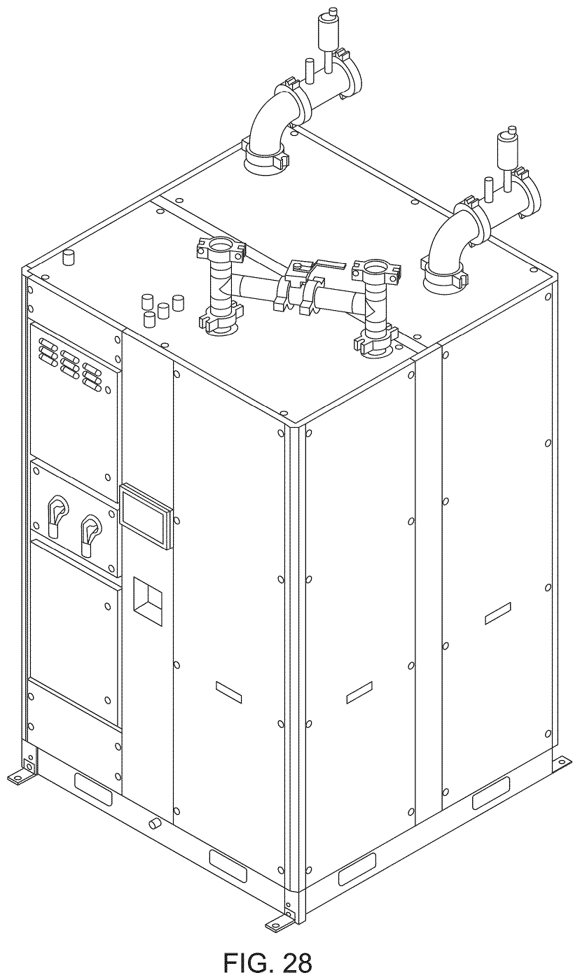

FIG. 28 illustrates another example of a coolant distribution unit (CDU) in accordance with aspects of the disclosure. As described herein, the CDU manages the transfer of thermal energy between a facility cooling fluid loop, e.g., a chilled water loop, and a technology cooling fluid loop. The CDU may include a modular enclosure. To facilitate maintenance and servicing, the CDU includes access doors on at least two sides. The back side of the CDU includes an interface display, which provides users with an interface for monitoring and controlling the CDU's operations. Temperature, pressure, and/or flow rates may be displayed on the display in real-time, enabling efficient system management and diagnostics.

The CDU includes two sets of fluid loop connections. On the top of the CDU, smaller-diameter supply and return pipe connections are designed to integrate seamlessly with the facility cooling fluid loop, such as a chilled water loop. These connections may be compatible with standard pipe fittings, simplifying installation. Larger-diameter supply and return pipe connections, also located on the top of the CDU, are designed for the demands of the technology cooling fluid loop.

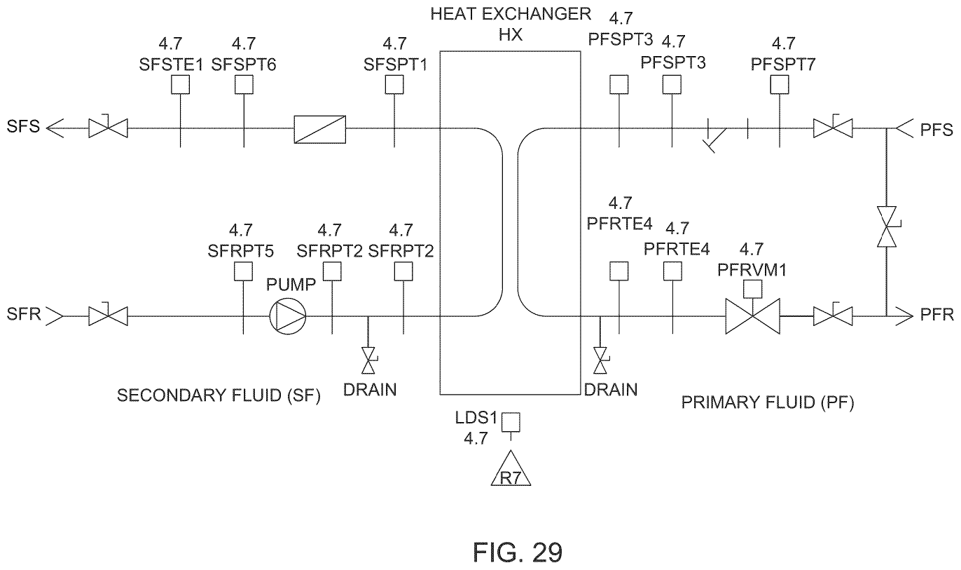

FIG. 29 illustrates an example of a fluid circuit housed in the CDU of FIG. 28. The fluid circuit includes a heat exchanger that facilitates thermal energy transfer between a primary fluid circuit and a secondary fluid circuit while maintaining control over temperature and pressure. The primary fluid circuit includes a supply line monitored by a supply temperature sensor (PFSTE3) and an inlet pressure transmitter (PFSPT3). The primary fluid, e.g., chilled water, flows through the heat exchanger, transferring heat to the secondary fluid, before exiting through a return line including a temperature sensor (PFRTE4) and a return pressure transmitter (PFRPT4). To regulate flow and pressure, a motorized valve (PFRVM1) adjusts the return fluid dynamics, ensuring consistent operational performance.

The secondary fluid circuit includes components like the primary fluid circuit to achieve optimal performance. A supply temperature sensor (SFSTE1) and an outlet pressure transmitter (SFSPT1) monitor the incoming fluid's thermal and pressure characteristics. The secondary fluid, which may be water, water solution, or a refrigerant, passes through the heat exchanger, absorbing thermal energy from the primary fluid, before returning through a return line with a return temperature sensor (SFRTE2) and pressure transmitter (SFRPT2). A leak detection switch (LDS1) may be placed in the secondary fluid loop to provide immediate alerts in case of fluid leaks. Additionally, the secondary fluid circuit incorporates a filtration unit to maintain fluid purity, thereby extending the data center cooling system's operational life and reducing maintenance demands.

Pressure transmitters (PFSPT3, PFSPT7, SFSPT1, SFSPT6) are disposed on both sides of the primary and secondary filtration units, e.g., the strainer of the primary fluid circuit, to enable monitoring of pressure differentials. Threaded plugs may be installed in all drain valve outlets to prevent fluid leakage during servicing. The fluid circuit may also include a pressure relief valve between the secondary fluid pump discharge and the isolation valve. This ensures that the data center cooling system operates within safe pressure limits, protecting components from over-pressurization.

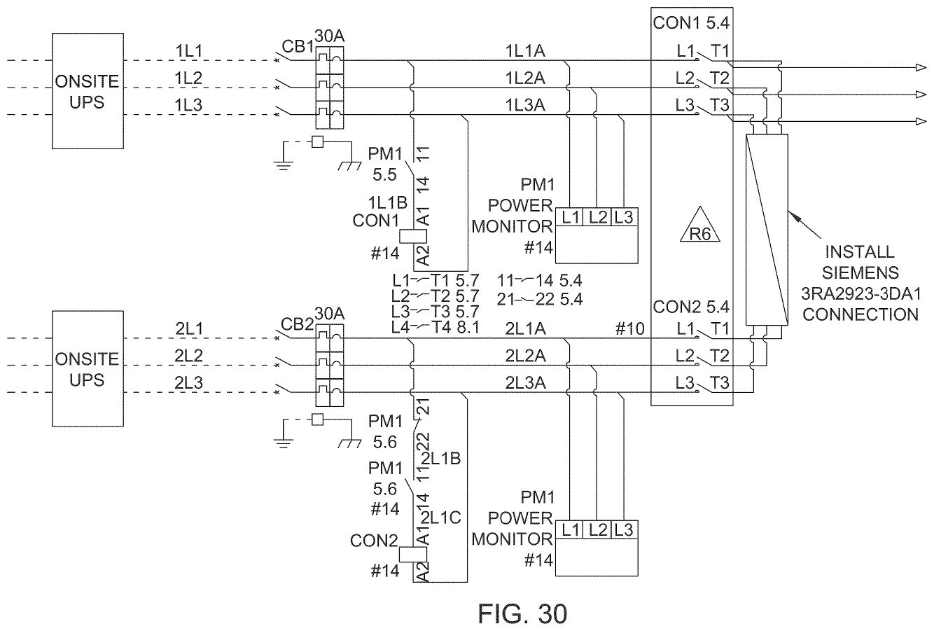

FIGS. 30-36 illustrate an example of an electrical system for the CDU of FIG. 28. FIG. 30 illustrates a power monitoring and distribution system configured for a three-phase electrical power. The power monitoring and distribution system ensures precise control, reliable power management, and operational safety. The system is powered by a three-phase electrical supply via input lines L1, L2, and L3. Input lines L1, L2, and L3 lines are coupled to circuit breakers CB1 and CB2, which provide overcurrent protection and enable circuit isolation during maintenance or fault conditions. Downstream of the circuit breakers, the three-phase lines connect to contactors CON1 and CON2, which are electrically operated switches, which enable or interrupt the flow of power to various system components based on operational commands or fault scenarios.

Each contactor CON1 and CON2 connects to a power monitor PM1 and PM2, which monitor electrical parameters including voltage, current, and power factor. The data collected by the power monitors PM1 and PM2 is transmitted to a programmable logic controller (PLC), which processes the information and provides feedback to the operator via a Human-Machine Interface (HMI). The HMI interface allows for real-time monitoring of system performance and manual adjustments or diagnostics.

The contactors CON1 and CON2 control power delivery to the system. The contactors CON1 and CON2 are actuated based on signals from the PLC. The electrical system includes redundant power monitors, which allows for continuous operation in the event of a fault in one of the power monitors PM1 and PM2.

Terminals T1, T2, and T3 are positioned between the contactors CON1 and CON2 and downstream components. Terminals T1, T2, and T3 distribute power to the connected circuits while maintaining a secure and stable electrical connection. The use of the wiring module (e.g., the Siemens 3RA2923-3DA1) ensures robust connections and compatibility with industrial standards.

In addition to power monitoring, the system includes safety features such as fault detection and automatic circuit isolation. The PLC monitors for abnormal conditions, such as overcurrent or voltage imbalances, and commands the contactors CON1 and CON2 to disconnect affected circuits. This prevents damage to downstream components and enhances the overall safety of the system.

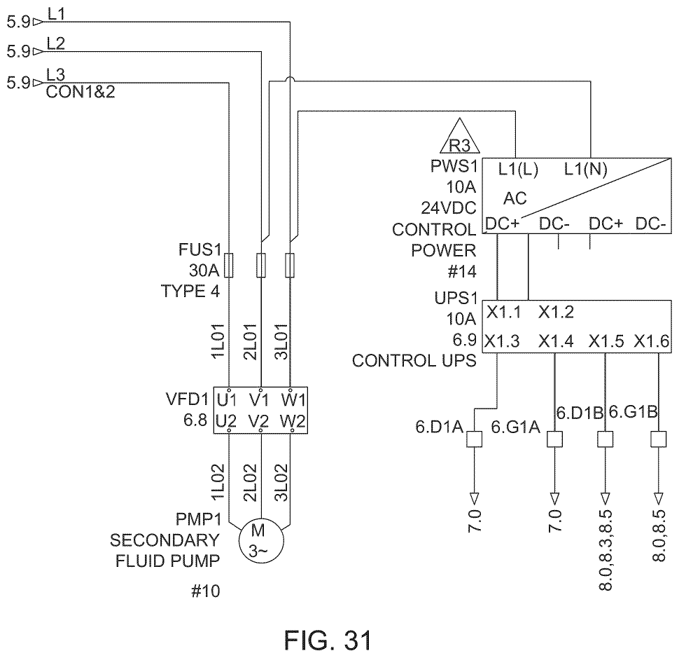

FIG. 31 illustrates another aspect of the CDU's power distribution and control system. The power input lines L1, L2, and L3 supply three-phase power through fuses FUS1 to terminals 1L01, 2L01, and 3L01. From terminals 1L01, 2L01, and 3L01, the power flows through the variable frequency drive (VFD) to corresponding nodes 1L02, 2L02, and 3L02, which couple to the terminals of the secondary fluid pump.

The VFD receives input power through terminals U1, V1, and W1. The VFD regulates the operation of the secondary fluid pump (PMP1) by modulating the frequency of the input power. This modulation allows precise control of the pump's motor speed, which enables the system to control fluid flow rates to meet operational demand. The output of the VFD is coupled through terminals U2, V2, and W2 to the motor of the secondary fluid pump (PMP1). The CDU also incorporates an uninterruptible power supply (UPS), which is coupled to a 24 VDC power supply (PWS). The PWS provides low-voltage power to the secondary fluid pump.

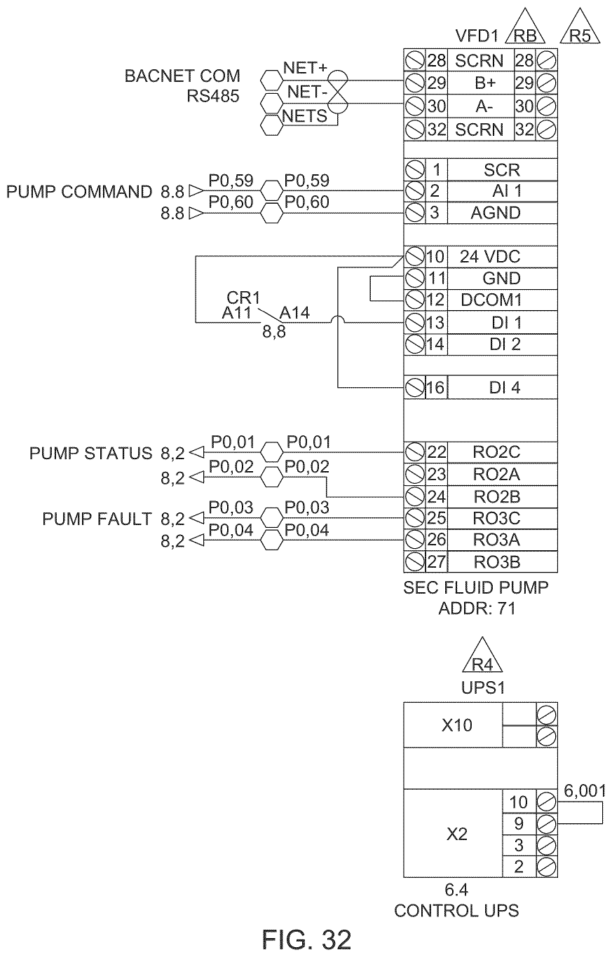

FIG. 32 illustrates other features of the secondary fluid pump control system. The secondary fluid pump is assigned a unique network address for seamless integration into a centralized control network. This feature supports real-time monitoring, which allows operators to monitor pump operations and identify performance trends or potential issues.

The secondary fluid pump's operation is governed by diagnostic and control features, including “Pump Status,” “Pump Fault,” and “Pump Command.” The “Pump Status” signal provides feedback, for example, confirming that the pump is properly functioning. The “Pump Fault” indicator triggers alerts for any operational anomalies, such as pressure irregularities or mechanical faults. The “Pump Command” signal controls the pump's operation. The “Pump Command” signal adjusts operational parameters, such as flow rates or start/stop cycles, based on the system's current demands. The system uses the RS485 communication protocol for seamless integration with supervisory control systems like SCADA.

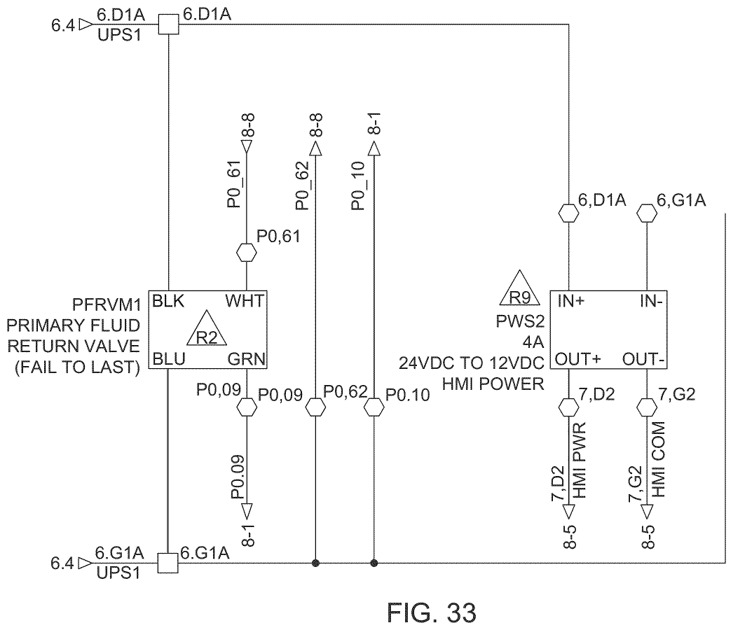

FIG. 33 illustrates an example of how power is supplied to the motor of the primary fluid return valve and to the HMI. In the example of FIG. 33, 24 VDC is supplied from the UPS to the motor of the primary fluid return valve and to a power converter for the HMI. In this example, the power converter converts the UPS's 24 VDC to 12 VDC, which is compatible with the HMI.

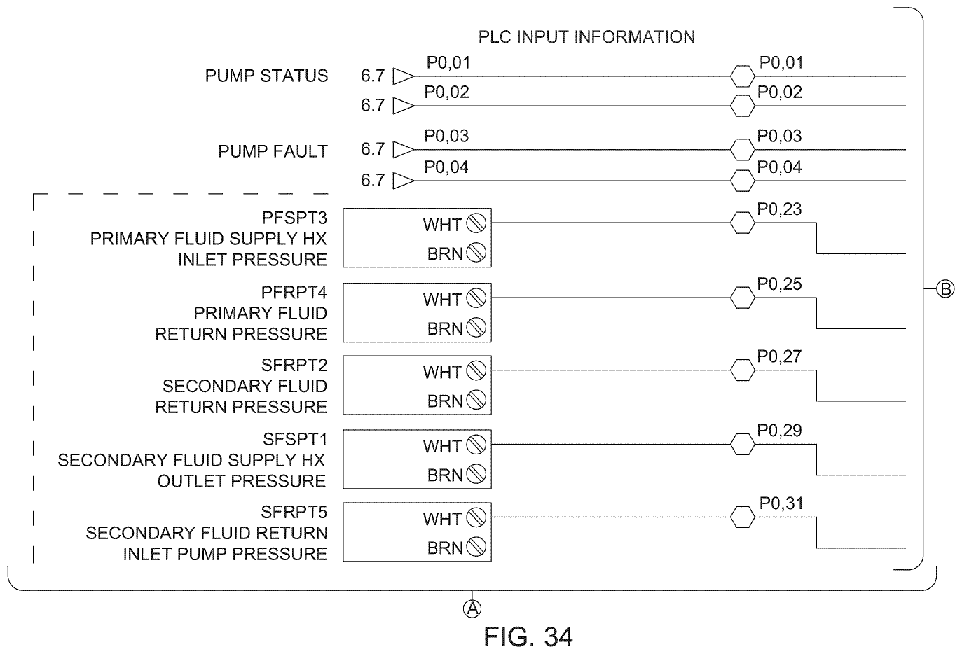

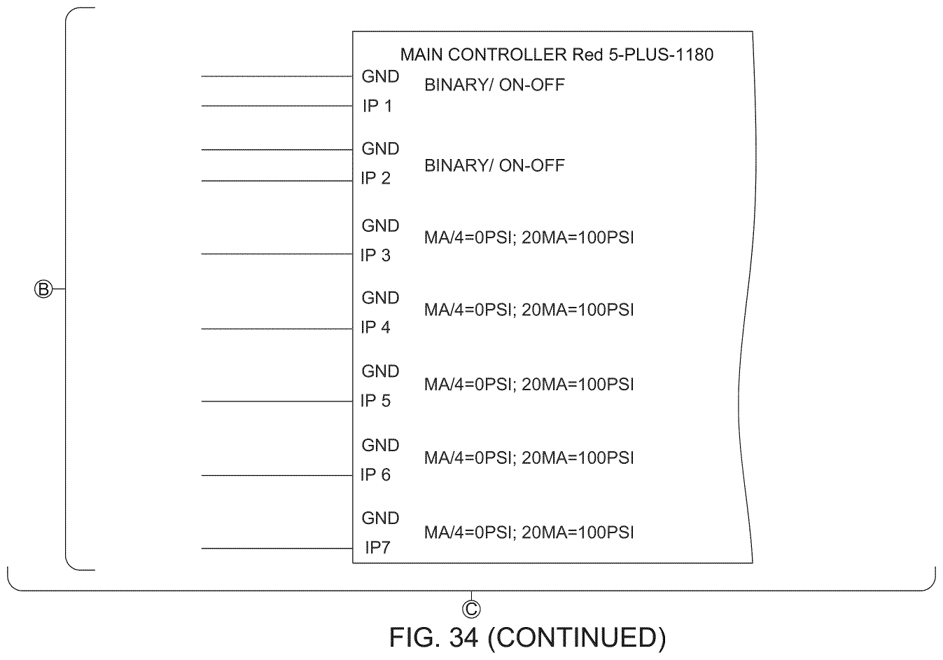

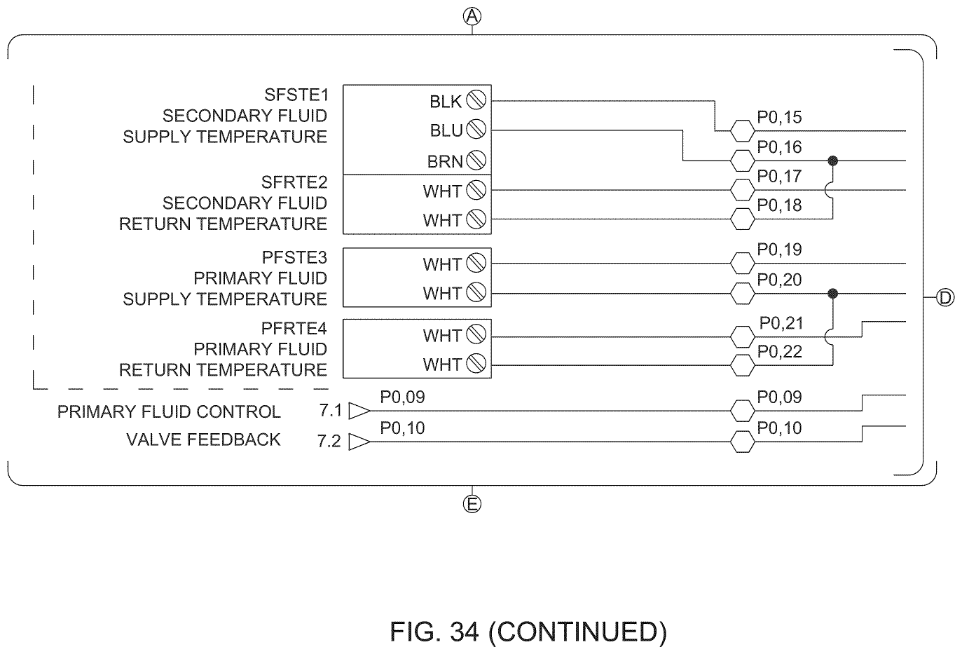

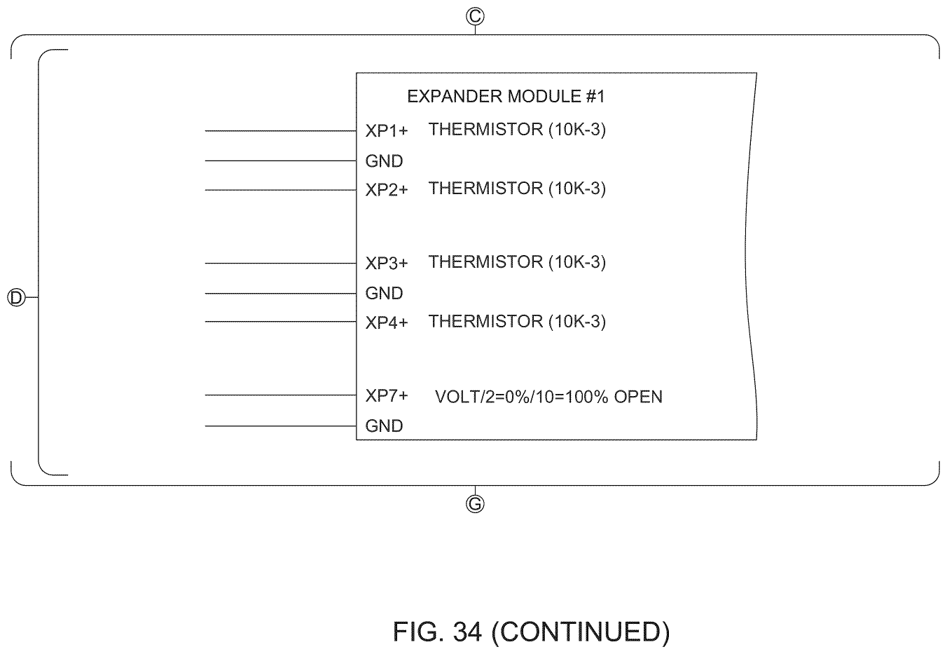

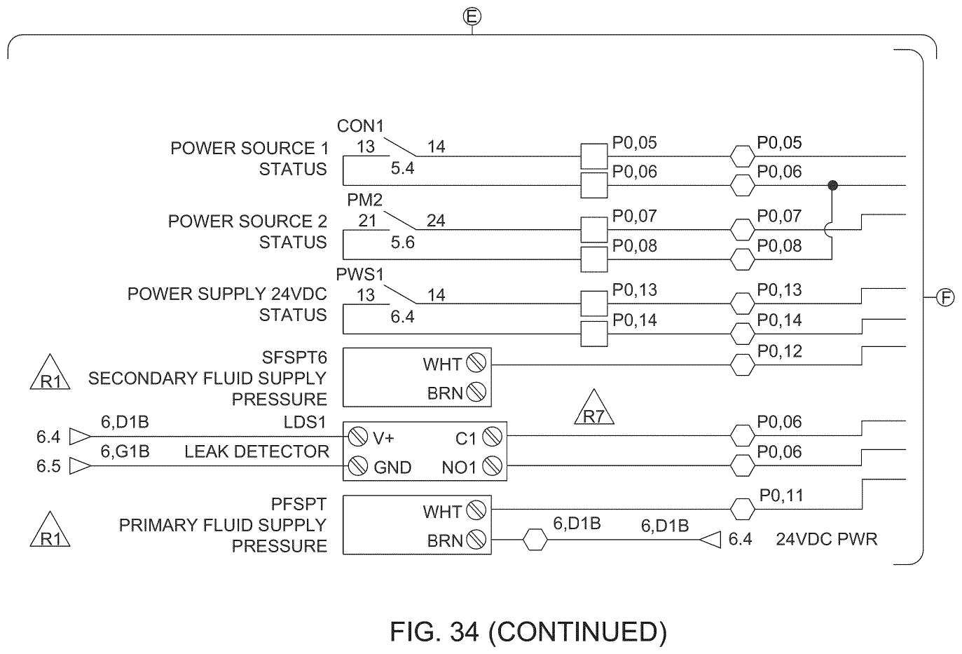

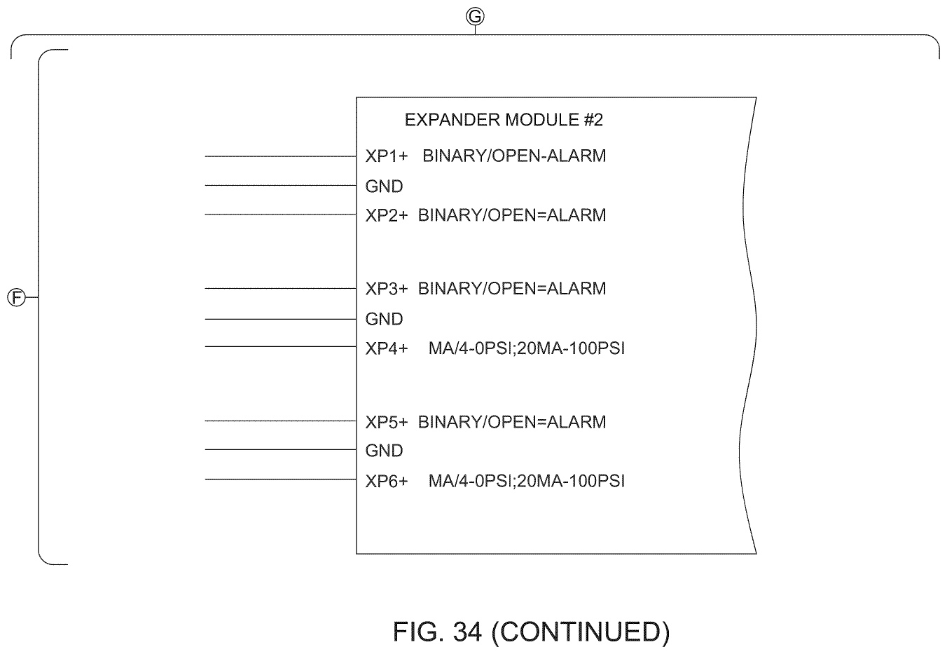

FIG. 34 illustrates a Programmable Logic Controller (PLC) which may be used to control features of the CDU. The PLC includes a main controller, which may function as the primary processing hub. The PLC receives input data from an array of sensors and transmitters described below. Supplementary processing capacity may be provided by two expander modules.

The main controller processes various inputs including binary inputs, which provide real-time status updates. For example, the PUMP STATUS input signals whether the pump is active or inactive. Similarly, the PUMP FAULT input alerts the PLC to any malfunctions or deviations from expected behavior. Another binary input is the VALVE FEEDBACK signal, which confirms the current position of control valves.

In addition to binary signals, the main controller interprets analog signals from pressure transmitters. The Primary Fluid Supply Pressure Transmitter (PFSPT3) and Return Pressure Transmitter (PFRPT4) measure the fluid pressures at the inlet and outlet of the primary side of the heat exchanger, respectively. These transmitters may use a standard 4-20 mA signal, with 4 mA corresponding to 0 PSI and 20 mA corresponding to 100 PSI, for example. This same signal range may be applied to the Secondary Fluid Pressure Transmitters, such as SFSPT1, which monitors the outlet pressure of the secondary side of the heat exchanger, and SFRPT2, which tracks the returning secondary fluid pressure.

The main controller receives input from thermistors installed throughout the CDU's fluid circuit. The inputs include the Primary Fluid Supply Temperature Sensor (PFSTE3) and the Return Temperature Sensor (PFRTE4), which measure the temperatures at the inlet and outlet of the primary side of the heat exchanger. Correspondingly, the Secondary Fluid Supply Sensor (SFSTE1) and Return Sensor (SFRTE2) perform similar functions within the secondary fluid circuit. Each thermistor may be calibrated to 10K to obtain precise temperature measurements.

To extend its monitoring capacity, the system integrates two expander modules, which augment the main controller by processing additional inputs. Expander Module #1 primarily handles thermistor-based temperature inputs, e.g., inputs from sensors XP1+ and XP2+. These inputs provide detailed temperature readings from specific points in the fluid circuit to understand fluid dynamics.

Expander Module #2 complements this functionality by focusing on alarm inputs and supplementary pressure monitoring. Binary alarm inputs, such as XP1+ and XP2+, trigger alerts whenever specified conditions are met, such as valve misalignment or pressure anomalies. Additionally, this Expander Module #2 receives analog input from the Secondary Fluid Supply Pressure Transmitter (SFSPT6), which provides real-time pressure data using the same 4-20 mA scaling as the primary controller inputs. Thus, the main controller and the expander modules of the PLC ensure that the fluid circuit of the CDU is continuously monitored and dynamically adjusted.

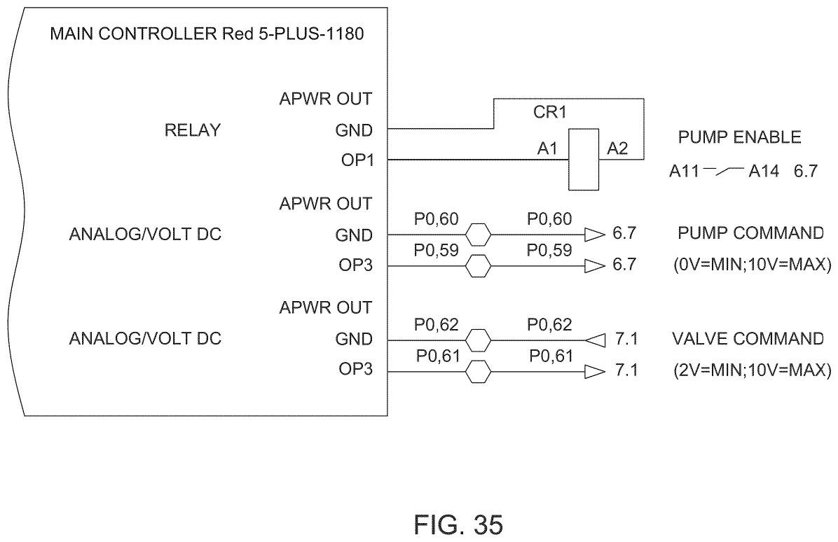

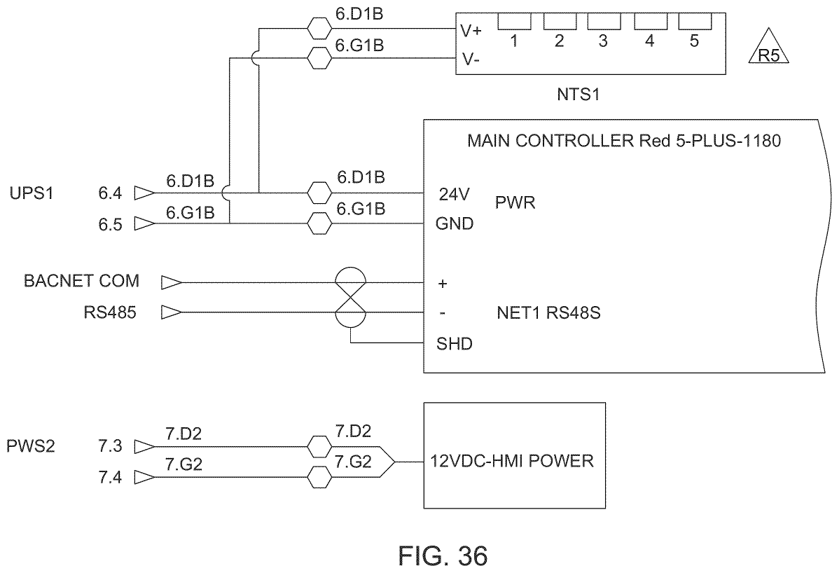

As shown in FIG. 35, the main controller of the PLC also includes output ports designed for operation of external devices. The Pump Enable output is a binary signal used to activate or deactivate the secondary fluid pump. The Pump Command output provides an analog signal ranging from 0V to 10V to control the secondary fluid pump's speed. The Valve Command output from the main controller delivers an analog signal ranging from 2V to 10V, which controls valve positions to regulate fluid flow. Also, as illustrated in FIG. 36, the main controller of the PLC is connected to an Uninterruptible Power Supply (UPS1) for power redundancy. This guarantees continuous operation of the main controller during power outages or disruptions.

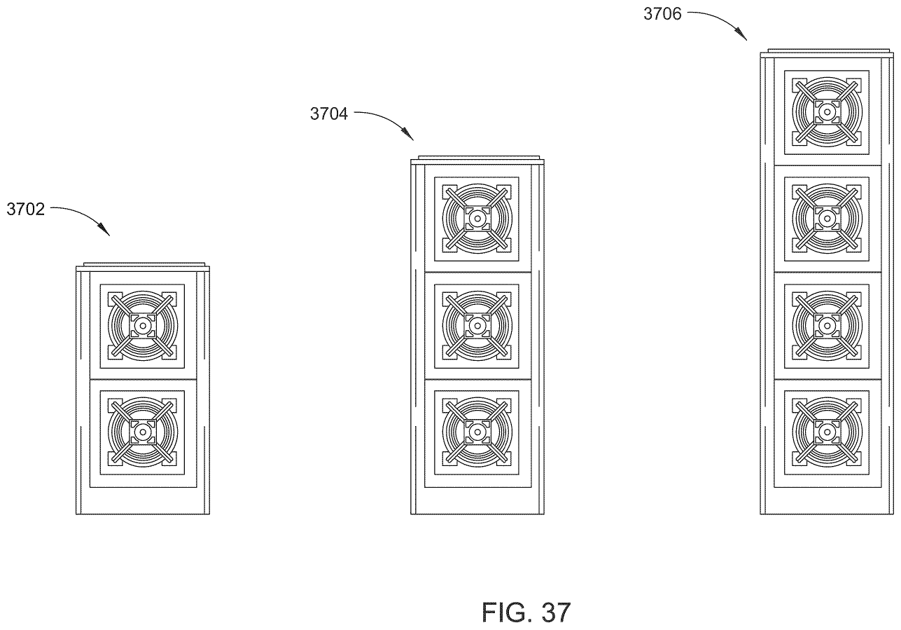

FIG. 37 are front views of fan and heat exchanger arrays in accordance with aspects of the disclosure. FIG. 37 shows examples of fan and heat exchanger modules or assemblies assembled to form larger arrays of fan and heat exchanger assemblies, which are also referred to herein as air-cooling units. In embodiments, two, three, or four fan and heat exchanger modules may be stacked to form stacked or arrays of fan and heat exchanger modules 3702, 3704, and 3706, respectively. In aspects, any number of the stacked fan and heat exchanger modules 3702, 3704, and 3706 may be connected side-by-side, e.g., six stacks may be connected side-by-side.

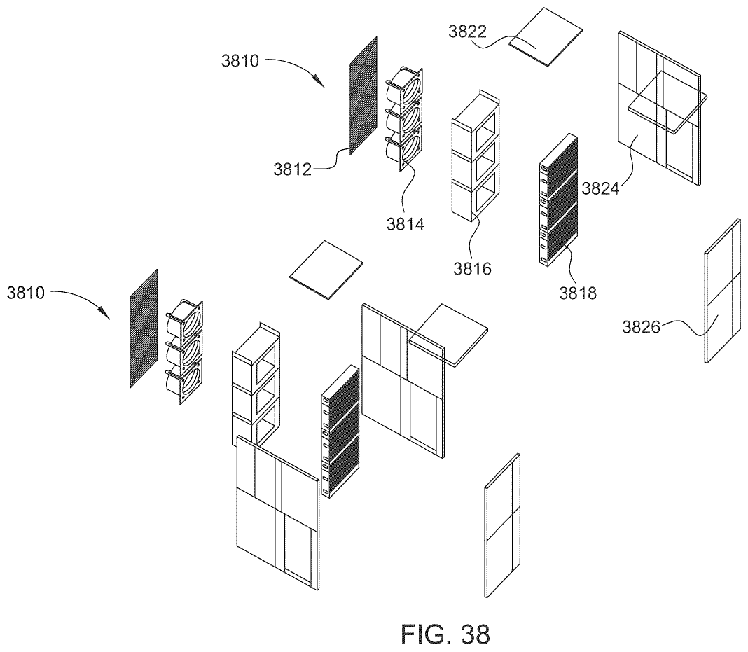

FIG. 38 is an exploded view of a fan and heat exchanger array assembly including two fan and heat exchanger arrays 3810. The stacked fan and heat exchanger modules 3810 include fan guards 3812 (e.g., three fan guards), variable-speed fans 3814 (e.g., three variable-speed fans), fan housings 3816 (e.g., three fan housings configured to be coupled to each other), and heat exchangers 3818 (e.g., three heat exchangers configured to be coupled to each other). The enclosure assemblies, which may include panels 3822, 3824, and 3826, and the stacked fan and heat exchanger modules 3810 may be shipped as partially assembled kits.

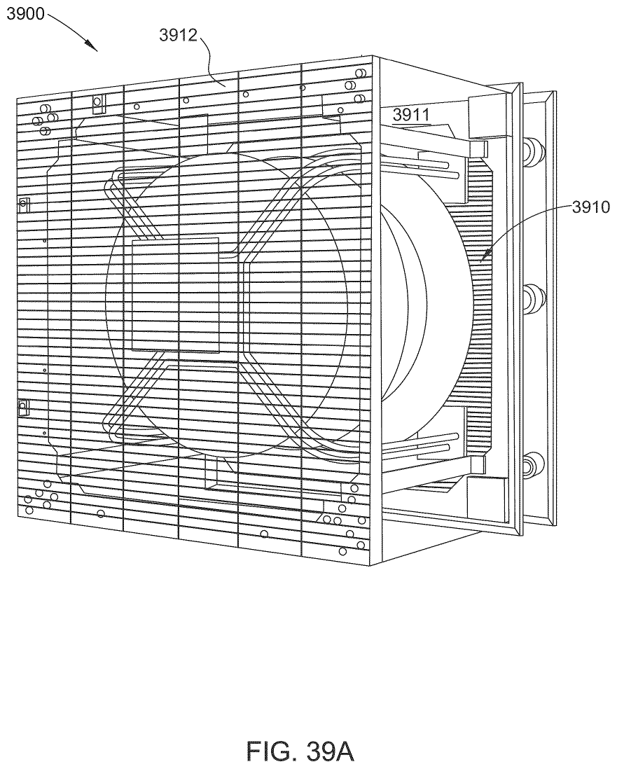

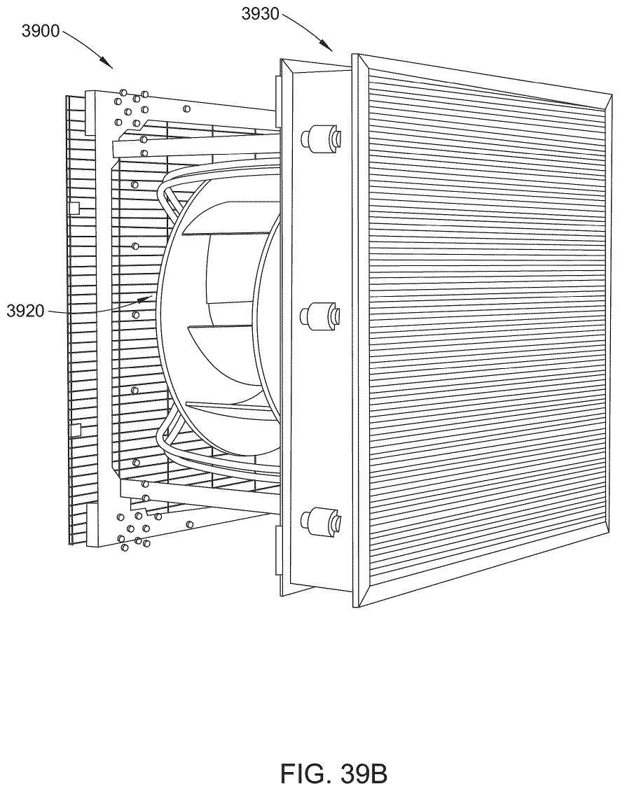

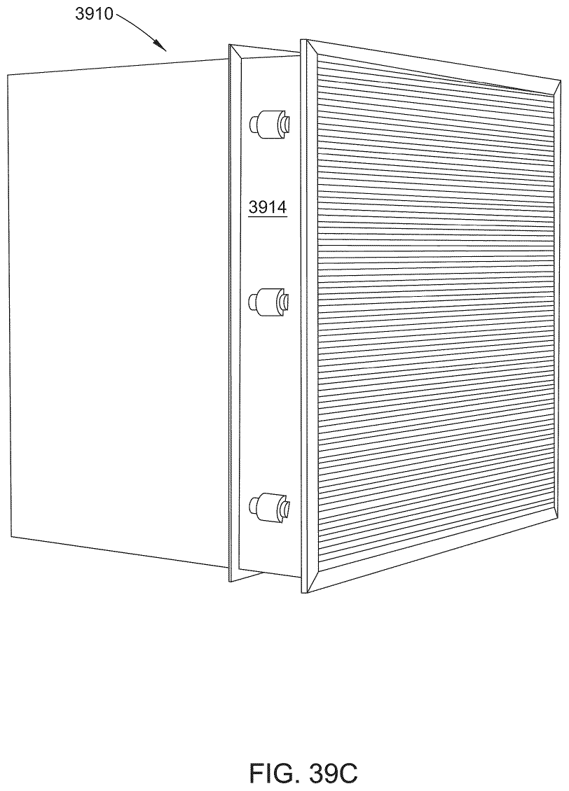

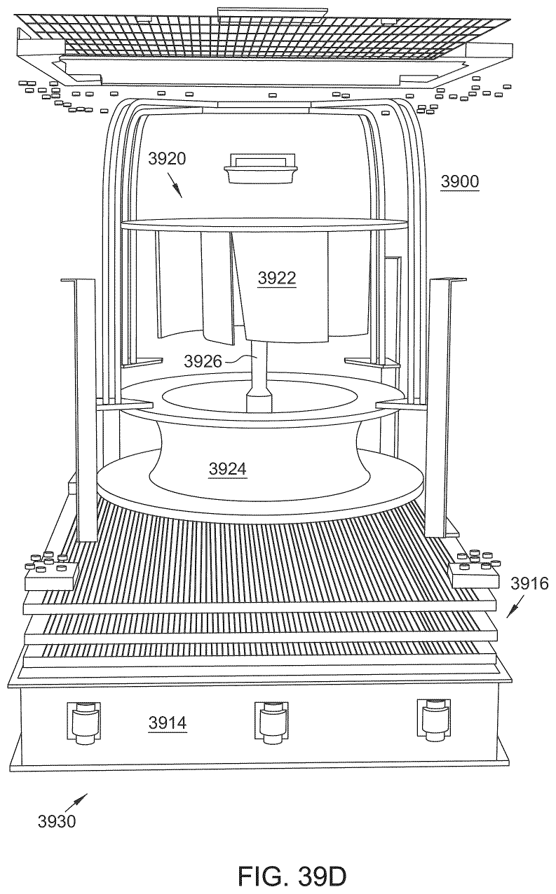

FIGS. 39A-39D illustrate a fan and heat exchanger assembly 3900 according to aspects of the disclosure. The fan and heat exchanger assembly 3900 includes an enclosure 3910 that houses an axial fan 3920, which may be a high-performance axial fan, and a heat exchanger 3930. In aspects, the axial fan 3920 and heat exchanger 3930 may be integrated together to form a single unit. For example, the enclosure 3910 may be designed as a common enclosure for the axial fan 3920 and the heat exchanger 3930. The single unit may include features that promote modularity. For example, the single unit may include attachment or connection features that allow single units to be easily stacked and attached to one another. The single unit may include heat exchanger fluid lines designed to easily connect to heat exchanger fluid lines of another single unit. The enclosure 3910 may be a durable metal frame with a grille 3912 and a stack frame 3914 for securing stacks 3916 of arrays of thermally conductive fins interspersed with fluid-carrying tubes, which may be fluidically coupled to the facility fluid loop, e.g., a chilled water loop.

The axial fan 3920 may be centrally positioned within the enclosure 3910 and may include a multi-bladed rotor 3922 designed for high airflow and pressure performance. The multi-bladed rotor 3922 is mounted to a central hub 3924 via a shaft 3926, which, in turn, is coupled to a motor (not shown) within the central hub 3924, e.g., a high-efficiency motor. The motor operates to drive the multi-bladed rotor 3922 at variable speeds, ensuring the airflow is dynamically adjusted based on thermal demands. The aerodynamic profile of the fan blades may be optimized to minimize turbulence and noise.

The heat exchanger 3930 may be positioned upstream from the axial fan 3920 within an airflow path from the heat exchanger 3930 to the axial fan 3920. The heat exchanger 3930 may include one or more stacks of tightly packed arrays of thermally conductive fins interspersed with fluid-carrying tubes. In aspects, the fins may be constructed from an aluminum alloy to provide high thermal conductivity, while the tubes may be constructed from corrosion-resistant copper. Fluid circulates through the tubes, absorbing heat transferred from the fins of each of the heat exchanger stacks.

In aspects, the grille 3912 may be removable to provide access to the internal components of the fan and heat exchanger assembly 3900, for example, to provide access for maintenance tasks. Behind the grille 3912, the axial fan 3920 may be mounted on brackets coupled to a structural frame 3911 within the enclosure 3910. The heat exchanger 3920 may be secured to the structural frame 3911 using mounting bolts, ensuring stability during operation. The modular construction of the fan and heat exchanger assembly 3900 allows for scalability and customization according to aspects of the disclosure to meet cooling capacity requirements of one or more data center pods that include air-cooled IT equipment cabinets.

As used herein, the term “fluid” may refer to any fluid suitable for removing heat from IT equipment. For example, the fluid may include water, refrigerant, deionized water, glycol/water solutions, or dielectric fluids such as fluorocarbons and polyalphaolefin (PAO). The fluid may be a mixture of a liquid and another substance that does not dissolve in the liquid at a predetermined temperature and/or pressure. The other substance may be in a gaseous, liquid, or solid state.

Various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, the techniques of this disclosure may be performed by a combination of units or modules.

In one or more examples, the described techniques may be implemented in hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media (e.g., RAM, ROM, EEPROM, flash memory, or any other medium that can be used to store desired program code in the form of instructions or data structures and that can be accessed by a computer).

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor” as used herein may refer to any of the foregoing structure or any other physical structure suitable for implementation of the described techniques. Also, the techniques could be fully implemented in one or more circuits or logic elements.

1. A cooling system comprising:
a coolant distribution unit (CDU) including:
a heat exchanger configured to be fluidically coupled to a facility cooling fluid circuit;
a fluid pump fluidically coupled to the heat exchanger and configured to pump cooling fluid to at least a portion of Information Technology (IT) cabinets of two rows of the IT cabinets defining a hot aisle;
an electrical panel electrically coupled to the fluid pump; and
control panel electrically coupled to the electrical panel and operationally coupled to the fluid pump; and
an array of fan and heat exchanger modules fluidly coupled to the facility cooling fluid circuit and disposed adjacent to the CDU, the array of fan and heat exchanger modules configured to circulate air through the hot aisle.

2-4. (canceled)

5. The cooling system of claim 1, wherein a fluid line is fluidically coupled between the fluid pump and the heat exchanger.

6. The cooling system of claim 5, further comprising supply and return line coupling members coupled to a side of the CDU,
wherein the supply and return line coupling members include quick-connect fittings.

7. The cooling system of claim 5, wherein the fluid pump is a liquid pump.

8. (canceled)

9. A data center assembly comprising:
a first array of Information Technology (IT) equipment cabinets;
a second array of IT equipment cabinets disposed adjacent to the first array of IT equipment cabinets to define a hot aisle;
an air containment assembly fluidically coupled to the hot aisle;
at least one array of fan and heat exchanger modules fluidically coupled to the air containment assembly; and
at least one fluid-cooling system fluidically coupled to at least a portion of the IT equipment cabinets, the at least one fluid-cooling system including:
a heat exchanger fluidically coupled to a portion of the first and second arrays of IT equipment cabinets, and fluidically coupled to a facility fluid cooling loop;
a fluid pump fluidically coupled to the heat exchanger;
an electrical panel electrically coupled to the fluid pump; and
control panel electrically coupled to the electrical panel and operationally coupled to the fluid pump.

10-45. (canceled)

46. A data center pod comprising:
a first array of Information Technology (IT) equipment cabinets;
a second array of IT equipment cabinets disposed adjacent to the first array of IT equipment cabinets to define a first hot aisle;
an air containment assembly fluidically coupled to the first hot aisle;
at least one air-cooling unit fluidically coupled to the air containment assembly;
a technology liquid loop;
at least one liquid distribution unit fluidically coupled through the technology liquid loop to a portion of the IT equipment cabinets, the at least one liquid distribution unit including:
a heat exchanger fluidically coupled to a cooling liquid loop and to the technology liquid loop, the heat exchanger configured to facilitate heat transfer from the technology liquid loop to the cooling liquid loop; and
a fluid pump fluidically coupled to the technology liquid loop.

47. The data center pod of claim 46, wherein the IT equipment cabinets are server racks.

48. The data center pod of claim 46, wherein the at least one air-cooling unit includes at least two fan and heat exchanger assemblies.

49. The data center pod of claim 46, wherein at least one dimension of the at least one air-cooling unit is the same as or substantially the same as at least one dimension of the at least one liquid distribution unit.

50. The data center pod of claim 49, wherein the at least one dimension is width.

51. The data center pod of claim 49, wherein the at least one dimension is width and height.

52. (canceled)

53. (canceled)

54. The data center pod of claim 46, wherein the at least one liquid distribution unit further includes a strainer fluidically coupled to the fluid pump.

55. The data center pod of claim 46, wherein the at least one liquid distribution unit further includes isolation valves fluidically coupled to the technology liquid loop.

56. The data center pod of claim 46, wherein the at least one air-cooling unit is designed to be or substantially to be interchangeable with the at least one liquid distribution unit.

57. The data center pod of claim 46, wherein the IT equipment cabinets include air-cooled IT equipment cabinets and liquid-cooled IT equipment cabinets.

58. The data center pod of claim 57, wherein the air-cooled IT equipment cabinets are disposed between the liquid-cooled IT equipment cabinets.

59. The data center pod of claim 46, further comprising:
a third array of IT equipment cabinets;
a fourth array of IT equipment cabinets disposed adjacent to the third array of IT equipment cabinets to define a second hot aisle;
a second air containment assembly fluidically coupled to the second hot aisle; and
technology liquid branch lines fluidically coupled to a portion of the IT equipment cabinets and to the technology liquid loop.

60. The data center pod of claim 59, wherein the technology liquid branch lines are disposed above or below the first hot aisle and the second hot aisle.

61. The data center pod of claim 59, wherein liquid-cooled IT equipment cabinets include fluid line connectors coupled to a top portion or a side portion of the liquid-cooled IT equipment cabinets.

62. The data center pod of claim 61, further comprising connection lines fluidically coupled between the technology liquid branch lines and the fluid line connectors.

63. (canceled)
